(19) United States
(12) Patent Application Publication
(10) Pub. No.: US 2013/0149500 A1
(43) Pub. Date: Jun. 13, 2013

(54) SOFT-TEMPLATE INFILTRATION MANUFACTURING OF NANOMATERIALS

(71) Applicants: Nazanin Bassiri-Gharb, Atlanta, GA (US); Ashley L. Bernal, Terre Haute, IN (US)

(72) Inventors: Nazanin Bassiri-Gharb, Atlanta, GA (US); Ashley L. Bernal, Terre Haute, IN (US)

(21) Appl. No.: 13/706,376

(22) Filed: Dec. 6, 2012

Related U.S. Application Data
(60) Provisional application No. 61/567,391, filed on Dec. 6, 2011.

(51) Int. Cl. B81B 1/00; B05D 3/02

(52) U.S. Cl. CPC B81B 1/00; B05D 3/0254
USPC 428/156; 427/264; 427/600

(57) ABSTRACT

Nanostructured materials, devices having nanostructured materials, and methods for preparing nanostructured materials are disclosed herein. In some embodiments, the method includes infiltrating a soft template with a chemical precursor and subsequently heat treating the infiltrated template to produce a nanostructured material. The soft template can be a patterned soft template, where the pattern is created in a soft template precursor and defined by the user to place structural features at specified locations. In some embodiments, nanostructured materials can be ferroic nanostructures, including ferroelectric and ferromagnetic nanomaterials, having a user defined pattern and favorable structural characteristics, including defined aspect ratios, wall thicknesses, and other dimensions.

### CROSS-REFERENCE TO RELATED APPLICATIONS

This application claims the benefit of U.S. Provisional Application Ser. No. 61/567,391, filed on 6 Dec. 2011, entitled “Soft-template Infiltration Manufacturing of Nanomaterials” which is incorporated herein by reference in its entirety as if fully set forth below.

### TECHNICAL FIELD

The various embodiments of the disclosure relate generally to nanomaterials and their associated fabrication processes, and more particularly to high aspect ratio, user-defined nanostructures and to methods for making such structures.

### BACKGROUND

Because nanomaterials possess unique chemical, physical and mechanical properties, they have the potential for wide-ranging industrial, biomedical and electronic applications. Such applications can include computer chips, biomaterials, composites, energy storage, drug delivery systems and optoelectronic materials. The manufacturing of nanomaterials has been the subject of enormous interest due to the widespread applications of such materials.

Ferroelectric nanomaterials show the highest piezoelectric response currently available for technological applications. Accordingly, fabrication of nanostructured ferroelectric materials has become of increasing interest due to the numerous possible micro- and nanoscale device applications such as actively tunable photonic and phononic crystals, terahertz emitters, energy harvesters, micromotors, micropumps, and nanoelectromechanical sensors, actuators, and transducers. However, with the drive towards miniaturization, intrinsic and extrinsic size effects have emerged that lead to a reduction of the effective piezoelectric response of these materials at small scales.

Two approaches commonly used in manufacturing nanoscale ferroelectrics include top-down and bottom-up methods. Top-down manufacturing methods mostly leverage focused ion beam (FIB) milling; however, the high energy ion beam can induce surface damage and degrade the ferroelectric or piezoelectric response, thus limiting any technological application of the material. While bottom-up methods have shown more promising results for creation of nanoscale ferroelectrics, the methods are either restricted to producing low aspect ratio materials with site specific registry, or high aspect ratio structures without the ability to control the location of the pattern on the material. Therefore, the bottom-up techniques currently employed in the production of ferroelectric nanomaterials are incompatible with opto-electro-mechanical (OEM) device applications.

### BRIEF SUMMARY

Embodiments of the disclosure relates to the nanomaterials and associated fabrication methods. An exemplary embodiment of the disclosure provides a method of fabrication of high aspect ratio, user-defined nanomaterials.

An embodiment of the disclosure can be a method for fabrication of nanostructured materials having the steps of patterning a soft template, coating the patterned soft template with a conformal layer, infiltrating the soft template with a chemical precursor solution, and heat-treating the infiltrated template to form the nanostructured material. The soft template precursor can be a polymer film having a thickness of about 10 nm to 1 micron. In some embodiments, the soft template precursor can be a polymer film having a thickness of about 50 nm to 1 micron. In an alternative embodiment, the polymer film can have a thickness of about 100 nm to 1 micron.

In another embodiment, the polymer film can have a thickness of about 100 nm to 900 nm. In yet another embodiment, the polymer film can have a thickness of about 150 nm to 600 nm. In certain embodiments, the patterning step can create a user-defined pattern in the soft template precursor.

In some embodiments, the conformal layer can comprise a metal oxide, a metal, or a ceramic material. In an exemplary embodiment, the conformal layer can be Al₂O₃, titania, ZnO, zirconia, or Pt. The conformal layer can have a thickness of approximately 5 nm to 30 nm.

The infiltrating step can comprise immersing the coated soft template in the chemical precursor solution. In one embodiment, the infiltrating step comprises ultrasonic- or vacuum-assisted infiltration. In an exemplary embodiment, the infiltrating step comprises ultrasonic- and vacuum-assisted infiltration. The chemical precursor solution can be a ferroic material precursor. In an alternative embodiment, the chemical precursor solution can be an oxide material precursor. In another embodiment, the chemical precursor solution can be PbZr₁₋ₓTiₓ(O₃, PbTiO₃, BiFeO₃, SiO₂, HfO₂, titania, zirconia, KNbO₃, Bi₄Ti₃O₁₂, SrTi₄Bi₄O₁₅, Na_{0.5}Bi_{0.5}TiO₃, NiFe₂O₄, CoFe₂O₄, or (1-x)[Pb(Mg_{1/3}Nb_{2/3})O₃]-x[PbTiO₃], or mixtures thereof, where x is between 0 and 1. The chemical precursor solution can be a doped or solid solution precursor. In an exemplary embodiment, the chemical precursor solution can be doped PbZr₁₋ₓTiₓO₃.

The heat-treating step can have a first heat treatment and a second heat treatment. In one embodiment, the first heat treatment is a pyrolysis to partially or completely remove a solvent from the chemical precursor solution. In another embodiment, the second heat treatment is a thermal annealing step to remove the soft template and crystallize the precursor. The heat-treating step can also be only one step, thermal annealing.

In an exemplary embodiment, the infiltrating step and the heat treatment step can be repeated. In yet another embodiment, the nanostructured materials can be etched to remove the top layer of the conformal layer or crystallized chemical precursor solution.

Another embodiment of the disclosure can be a method of fabricating a nanostructured material having the steps of infiltrating a soft template with a chemical precursor solution and subsequently heat treating the infiltrated template to produce the nanostructured material. In one embodiment, the soft template can be previously patterned with a user-defined pattern. In an alternative embodiment, the infiltrating can be ultrasonic- and vacuum-assisted infiltration.

An exemplary embodiment can be a ferroic nanostructure having an aspect ratio of about 1:1 to about 20:1. In another embodiment, the nanostructure can have an aspect ratio of about 1:1 to about 10:1. In an alternative embodiment, the nanostructure can have an aspect ratio of about 2:1 to about 5:1.

The ferroic nanostructure can be a nanotube, a nanopillar, or a nanoarchitecture. The nanostructure can have an outer diameter of about 30 nm to about 500 nm. In one embodiment, the nanostructure can have a height of about 50 nm to about 1 micron. In a further embodiment, the nanostructure can have a height of about 150 nm to about 500 nm. In certain embodiments, the nanostructure can have a wall thickness of at least about 5 nm, at least about 10 nm, or at least about 50 nm. The nanostructure can have user-defined patterns of ferroic nanostructures.

Another exemplary embodiment can be a piezoelectric device having a ferroic nanostructure. In one embodiment, the piezoelectric device can have a ferroic nanostructure having an aspect ratio of about 1:1 to about 20:1. In another embodiment, the nanostructure can have an aspect ratio of about 1:1 to about 10:1. In an alternative embodiment, the nanostructure can have an aspect ratio of about 2:1 to about 5:1.

The ferroic nanostructure of the piezoelectric device can be a nanotube, a nanopillar, or a nanoarchitecture. The nanostructure can have an outer diameter of about 30 nm to about 500 nm. In one embodiment, the nanostructure can have a height of about 50 nm to about 1 micron. In a further embodiment, the nanostructure can have a height of about 150 nm to about 500 nm. In certain embodiments, the nanostructure can have a wall thickness of at least about 5 nm, at least about 10 nm, or at least about 50 nm. The nanostructure can have user-defined patterns of ferroic nano structures.

These and other aspects of the disclosure are described in the Detailed Description below and the accompanying figures. Other aspects and features of embodiments of the disclosure will become apparent to those of ordinary skill in the art upon reviewing the following description of specific, exemplary embodiments of the disclosure in concert with the figures. While features of the disclosure may be discussed relative to certain embodiments and figures, all embodiments of the disclosure can include one or more of the features discussed herein. Further, while one or more embodiments may be discussed as having certain advantageous features, one or more of such features may also be used with the various embodiments of the disclosure discussed herein. In similar fashion, while exemplary embodiments may be discussed below as device, system, or method embodiments, it is to be understood that such exemplary embodiments can be implemented in various devices, systems, and methods of the disclosure.

### BRIEF DESCRIPTION OF THE FIGURES

The following Detailed Description is better understood when read in conjunction with the appended drawings. For the purposes of illustration, there is shown in the drawings exemplary embodiments, but the subject matter is not limited to the specific elements and instrumentalities disclosed.

FIG. 1 illustrates depositing a soft template precursor on a substrate, in accordance with an exemplary embodiment of the disclosure.

FIG. 2 illustrates patterning the soft template, in accordance with an exemplary embodiment of the disclosure.

FIG. 3 illustrates coating the soft template via atomic layer deposition (ALD), in accordance with an exemplary embodiment of the disclosure.

FIG. 4 illustrates immersing the patterned soft template into a precursor, in accordance with an exemplary embodiment of the disclosure.

FIG. 5 illustrates ultrasound assisted vacuum filtration, in accordance with an exemplary embodiment of the disclosure.

FIG. 6 illustrates a heat treatment to crystallize the precursor and remove polymer, in accordance with an exemplary embodiment of the disclosure.

FIG. 7 illustrates the result of multiple infiltration steps, in accordance with an exemplary embodiment of the disclosure.

FIG. 8 illustrates removal of the top layer via ALD, in accordance with an exemplary embodiment of the disclosure.

FIG. 9a-e illustrate schematic representations of the processing steps, in accordance with an exemplary embodiment of the disclosure.

FIG. 9f-h illustrate SEM images of ferroelectric nanostructures processed via soft-template infiltration, in accordance with an exemplary embodiment of the disclosure.

FIG. 9i illustrates Micro-Raman spectra of PZT nanotube arrays and reference 270 nm-thick (111)- and (100)-oriented PZT films with thickness similar to the height of the nanotubes, in accordance with an exemplary embodiment of the disclosure.

FIG. 10a-f illustrate SEM images with key processing steps, in accordance with an exemplary embodiment of the disclosure.

FIG. 11a illustrates layouts of the models used for finite element calculations of the electric field distribution in the PZT film, in accordance with an exemplary embodiment of the disclosure.

FIG. 11b illustrates layouts of the models used for finite element calculations of the electric field distribution in the PZT/Al₂O₃ nanotube, in accordance with an exemplary embodiment of the disclosure.

FIG. 11c illustrates the electric field distribution in PZT/Al₂O₃ nanotubes as a function of PZT thickness under applied 1V, in accordance with an exemplary embodiment of the disclosure.

FIG. 11d illustrates the equivalent circuit resulting from the PZT/Al₂O₃ bilayer, in accordance with an exemplary embodiment of the disclosure.

FIG. 12a-b illustrates 1 μm×1 μm AFM contact mode topography scan of PZT nanotubes with 20 nm and 25 nm wall thicknesses, respectively, in accordance with an exemplary embodiment of the disclosure.

FIG. 13a illustrates size effects in PZT nanotubes via SS-PFM piezoresponse hysteresis loops (arbitrary units), in accordance with an exemplary embodiment of the disclosure.

FIG. 13b illustrates size effects in PZT nanotubes via remnant piezoresponse and coercive voltage, in accordance with an exemplary embodiment of the disclosure.

FIG. 13c illustrates size effects in PZT nanotubes via Rayleigh parameters ratio for PZT nanotubes as a function of wall thickness, in accordance with an exemplary embodiment of the disclosure.

FIG. 14a illustrates the piezoresponse of a single 100 nm diameter PZT tube via AFM topography scan 300 nm×300 nm, in accordance with an exemplary embodiment of the disclosure.

FIG. 14b illustrates the piezoresponse of a single 100 nm diameter PZT tube via SS-PFM amplitude, in accordance with an exemplary embodiment of the disclosure.

FIG. 14c illustrates the piezoresponse of a single 100 nm diameter PZT tube via SS-PFM phase, in accordance with an exemplary embodiment of the disclosure.

FIG. 14d illustrates the piezoresponse of a single 100 nm diameter PZT tube via SS-PFM piezoresponse, in accordance with an exemplary embodiment of the disclosure.

FIG. 15a-f illustrate a comparison of piezoresponse in PZT films and nanotubes as measured by PFM, in accordance with an exemplary embodiment of the disclosure.

FIG. 16a-b illustrate the piezoresponse amplitude and frequency, respectively, at 255 kHz of a single 100 nm PZT nanotube at 3 V_{ac}, in accordance with an exemplary embodiment of the disclosure.

FIG. 16c-d illustrate the piezoresponse amplitude and frequency, respectively, at 267 kHz of a single 100 nm PZT nanotube at 3 V_{ac}, in accordance with an exemplary embodiment of the disclosure.

FIG. 16e illustrates the SEM micrograph of an array of 100 nm-wide PZT nanotubes with a 4:1 aspect ratio and 500 nm pitch; inset shows an AFM contact mode topography scan, in accordance with an exemplary embodiment of the disclosure.

FIG. 17a-d illustrate SEM and BE-PFM output response for PZT nanotubes embedded in an ultrathin alumina matrix, in accordance with an exemplary embodiment of the disclosure.

FIG. 17e-h illustrate SEM and BE-PFM output response for semi-freestanding PZT nanotubes, in accordance with an exemplary embodiment of the disclosure.

FIG. 18a-d illustrate BE-PFM output responses for a single PZT nanotube after poling at +15 V_{dc}, in accordance with an exemplary embodiment of the disclosure.

FIG. 18e-h illustrate BE-PFM output responses for a single PZT nanotube after poling at −15 V_{dc}, in accordance with an exemplary embodiment of the disclosure.

FIG. 19a-d illustrate SS-PFM output responses for a single PZT nanotube, in accordance with an exemplary embodiment of the disclosure.

FIG. 20 illustrates a SEM micrograph of an array of free-standing PZT nanotubes removed from the underlying substrate over a top view of a virgin nanotube array, in accordance with an exemplary embodiment of the disclosure.

FIG. 21a-b illustrate electric field distribution for 1 V applied voltage in a ˜250 nm-high PZT/Al₂O₃ nanotube (20 nm-thick PZT, 10 nm-thick Al₂O₃) for hard-template processed samples, in accordance with an exemplary embodiment of the disclosure.

FIG. 21c-d illustrate electric field distribution for 1 V applied voltage in a ˜250 nm-high PZT/Al₂O₃ nanotube (20 nm-thick PZT, 10 nm-thick Al₂O₃) for soft-template processed samples, in accordance with an exemplary embodiment of the disclosure.

FIG. 22a illustrates SS-PFM piezoresponse hysteresis loops for hard-template (square) and soft-template (diamond) frown PZT nanotubes with 5:1 aspect ratio and 20 nm-thick walls, in accordance with an exemplary embodiment of the disclosure.

FIG. 22b illustrates a schematic of intermediate non-180° polarization rotation under applied electric field for a free-standing (left) and laterally constrained (right) domain, in accordance with an exemplary embodiment of the disclosure.

FIG. 23a illustrates SS-PFM piezoresponse-electric field hysteresis loops for free-standing PZT nanotubes with aspect ratio ranging from 2.5:1 to 5:1, in accordance with an exemplary embodiment of the disclosure.

FIG. 23b illustrates the extracted remnant piezoresponse and coercive field for free-standing PZT nanotubes with aspect ratio ranging from 2.5:1 to 5:1, in accordance with an exemplary embodiment of the disclosure.

FIG. 23c illustrates bias-dependence of the piezoresponse for PZT tubes with 5:1 aspect ratio and 100 nm outer diameters, in accordance with an exemplary embodiment of the disclosure.

FIG. 23d illustrates irreversible to reversible Rayleigh parameters' ratio as a function of aspect ratio for 100 nm (diamond) and 200 nm (square) outer-diameter PZT nanotubes, in accordance with an exemplary embodiment of the disclosure.

### DETAILED DESCRIPTION

Although preferred embodiments of the disclosure are explained in detail, it is to be understood that other embodiments are contemplated. Accordingly, it is not intended that the disclosure is limited in its scope to the details of construction and arrangement of components set forth in the following description or illustrated in the drawings. The disclosure is capable of other embodiments and of being practiced or carried out in various ways. Also, in describing the preferred embodiments, specific terminology will be resorted to for the sake of clarity.

It must also be noted that, as used in the specification and the appended claims, the singular forms “a,” “an” and “the” include plural referents unless the context clearly dictates otherwise.

Also, in describing the preferred embodiments, terminology will be resorted to for the sake of clarity. It is intended that each term contemplates its broadest meaning as understood by those skilled in the art and includes all technical equivalents which operate in a similar manner to accomplish a similar purpose.

Ranges may be expressed herein as from “about” or “approximately” one particular value and/or to “about” or “approximately” another particular value. When such a range is expressed, another embodiment includes from the one particular value and/or to the other particular value.

By “comprising” or “comprising” or “including” is meant that at least the named compound, element, particle, or method step is present in the composition or article or method, but does not exclude the presence of other compounds, materials, particles, method steps, even if the other such compounds, material, particles, method steps have the same function as what is named.

It is also to be understood that the mention of one or more method steps does not preclude the presence of additional method steps or intervening method steps between those steps expressly identified. Similarly, it is also to be understood that the mention of one or more components in a device or system does not preclude the presence of additional components or intervening components between those components expressly identified.

Various embodiments of the disclosure are directed to manufacturing nanostructured materials. The nanostructured materials can be prepared according to this disclosure. In an embodiment, a nanostructured material can be fabricated by infiltrating a soft template with a chemical precursor solution and subsequently heat treating the infiltrated template to produce the nanostructured material. In another embodiment, a soft template can be patterned, coated with a conformal layer, infiltrated with a chemical precursor solution and heat-treated to form a nanostructured material. In yet another embodiment, the fabrication of nanostructured materials can be achieved by the following steps. First, a soft template can be patterned to form a patterned soft template. Second, the patterned soft template can be coated with a conformal layer to form a coated soft template. Next, the coated soft template can be infiltrated with a chemical precursor solution to form an infiltrated template. The infiltrated template can then be heat-treated to form the nanostructured material.

One particular advantage of this disclosure is the ease of creation of user-defined size, shape, and location of the nanostructures, enabling fabrication of NEMS devices based on ferroic smart materials. Various optoelectric material device applications can be manufactured using the disclosure including, but not limited to actively tunable photonic and phononic crystals, terahertz emitters, nano generators, energy harvesters, micromotors, micropumps, and nanoelectromechanical sensor, actuators, transducers, ferroelectric random-access memories, and the like. Furthermore, this approach can be tailored for a variety of ceramic materials by appropriate choice of sol-gel precursors and processing temperatures. Finally, this nanomanufacturing method can be easily scaled for larger patterned areas, as it is limited only by the ability to apply a user defined pattern onto the soft template.

The soft template can generally be patterned on any substrate that can withstand processing temperatures required by the method. The substrate can be any material commonly known or used in the art including, but not limited to, silicon, silica glass, platinized silicon, gallium arsenide, fused quartz, and sapphire. In an embodiment, the substrate can be platinized silicon.

In some embodiments, a soft template precursor can be coated on a substrate. Various coating methods include any method for coating a substrate used by one of ordinary skill in the art. In one embodiment, the substrate can be coated via dip-coating. In an exemplary embodiment, the substrate can be coated via spin-coating.

The soft template precursor generally includes a resist. In some embodiments, the resist can be a polymer thin film. Various resists can be used, including but not limited to, positive-tone resists, negative-tone resists, molecular resists, and the like. In certain exemplary situations, the soft template precursor can be Ma-N2403™ (MicroChem™). In other embodiments, the soft template precursor can be Flowable Oxide Resist 16® (FOX 16). Many other electron beam resists and photoresists commonly known in the art can be used as the soft template precursor. In certain embodiments, the height of the nanostructure can be altered via varying the spin-coating deposition speed of the resist.

Patterning the soft template precursor can include various lithographic techniques. Choice of technique can be selected based on several factors, including the type of soft template precursor, type of user defined structures, size and dimensions, including aspect ratio, which might be desired for the final product, as well as other aspects. These techniques can include, but are not limited to, photolithography, electron/ion-beam lithography, X-ray lithography, interference lithography, step-growth lithography, nanoimprint lithography, shadow mask lithography, and the like. In an embodiment, the template can be patterned using nanoimprint lithography, electron/ion beam lithography, and photolithography. In an embodiment, the specific patterning technique can be electron-beam lithography.

In general, the thickness of the soft template can determine the height of the resulting nanostructures. The disclosure allows fabrication of user-defined shapes, location, and pattern variation across the same substrate. The soft template can be patterned to user-defined shapes. These shapes are not generally limited and can vary across the substrate. By way of example and not limitation, the three dimensional shapes based on a square, round, rectangular, rhomboidal, triangular, star-shaped, pentagonal, hexagonal, trapezoidal, and other shapes. In exemplary embodiments, the patterned shape of the soft template can determine the shape and location of the final nanostructure. For example, a pattern can be selected that produces a round cylinder as part of the pattern in the patterned soft template. That round cylinder can produce a nanocolumn or nanopillar as the nanostructured material. Moreover, the nanostructured material can be prepared such that a center portion of the nanostructure is empty or hollow, yielding a nanotube instead of a nanopillar.

The nature of the disclosure allows the bottom-up fabrication of user-defined shapes, location and patterns across the substrate. While top-down approaches can create a wide range of user-defined, in-plane shapes via methods such as focused ion beam milling, these methods are limited by the high energy ion beam that can degrade the ferroelectric and piezoelectric response. The disclosure overcomes such limitations by creating the nanostructures only where needed, i.e. with an additive approach rather than a subtractive approach. As a result, the need for the high energy beam removal of the material, as well as the resulting damage to the ferroic material, at a later stage can be avoided.

The soft template can be coated with a conformal layer via various processes. In one embodiment, the soft template can be coated using any method known to one of ordinary skill In an embodiment, the soft template can be coated using chemical solution deposition/sol-gel, plating, chemical vapor deposition, physical vapor deposition, atomic layer deposition, pulsed laser deposition. In one embodiment, the conformal layer can be a metal, a metal oxide, or a ceramic. In another embodiment the conformal layer can be a metal oxide. In some embodiments, the conformal layer can be Al₂O₃, titania, ZnO, zirconia, or Pt. The conformal layer can have a thickness of about 5 nm to about 100 nm, about 5 nm to about 50 nm, about 5 nm to about 30 nm, or about 5 nm to about 15 nanometers. The composition of the conformal layer can be tailored to chemically match a chemical portion of the chemical precursor, or can be tailored to complement the resulting nanostructure. In one non-limiting example, the conformal layer can be titania or zirconia, and can be paired with a lead zirconate or lead titanate, or bismuth titanate, such as for example, PbZr₁₋ₓTiₓO₃, or Bi₄Ti₃O₁₂. The conformal layer in this example can then be part of or incorporated into the final composite of the nanostructure. Therefore, in an embodiment, the conformal layer is a metal oxide. The metal oxide can chemically match a portion of the chemical precursor or chemically complement a portion of the chemical precursor. In an embodiment, the conformal layer can be a Pt, Cu, Ni, Pd, Fe, Co, Ag, La, or Mn, or alloys thereof. The conformal layer could be a metal, such as platinum, copper, nickel, palladium or silver, and alloys thereof, such that the final nanostructured material is in contact with an electrically conductive substance for further functionalization. The conformal layer can also be a metal that undergoes oxidation during heat treatment to provide a metal oxide in the nanostructured material, such as iron, cobalt, lanthanum or manganese, and alloys thereof.

The conformal layer-coated soft template can be infiltrated with a chemical precursor solution. In one embodiment, the infiltrating step can include ultrasonic- or vacuum-assisted infiltration. In an exemplary embodiment, the infiltrating step can include ultrasonic- and vacuum-assisted infiltration. Without wishing to be bound by theory, the infiltrating step herein described overcomes several aspects of template surface chemistry that would otherwise prevent the infiltration of the patterns in the soft template. Several surface chemistry events hinder the infiltration of these patterns. Tubes and channels created at a nanometer scale are known to possess superhydrophobic surfaces that are normally impermeable to solutions. Surface tensions, partial pressures inside the patterns, and capillary forces are also known to contribute to impermeability of patterned surfaces. Surprisingly, the patterns created in the patterned soft template can be infiltrated using the method of this disclosure, and the chemical precursor solution can be forced into the patterned area in the infiltration step by removing the air under vacuum and/or by immersion in an ultrasonic bath.

The chemical precursor solution can comprise one or solvents, and one or more solutes, as one of ordinary skill in the art would recognize. The chemical precursor solution can comprise a ferroic precursor or a multiferroic precursor. One of ordinary skill in the art would understand that ferroics are materials that have “ferrel” in their behavior, e.g. ferroelectric, ferroelastic, antiferroelectric, ferromagnetic, ferrimagnetic, etc. Multiferroic materials then exhibit more than one of these behaviors. The chemical precursor solution can included a ferroelectric precursor or a ferromagnetic precursor, or a combination of both. In an embodiment, the chemical precursor solution can be an oxide material precursor. In some embodiments, the chemical precursor solution can be one or more of PbZr₁₋ₓTiₓO₃, PbTiO₃, BiFeO₃, SiO₂, HfO₂, titania, zirconia, KNbO₃, Bi₄Ti₃O₁₂, SrTi₄Bi₄O₁₅, Na_{0.5}Bi_{0.5}TiO₃, NiFe₂O₄, CoFe₂O₄, and (1-x)[Pb(Mg_{1/3}Nb_{2/3})O₃]-x[PbTiO₃], where x is between 0 and 1. In some embodiments, the chemical precursor solution can be one or more of PbZr₁₋ₓTiₓO₃, PbTiO₃, BiFeO₃, (1-x)[Pb(Mg_{1/3}Nb_{2/3})O₃]-x[PbTiO₃], KNbO₃, Bi₄Ti₃O₁₂, SrTi₄Bi₄O₁₅, or Na_{0.5}Bi_{0.5}TiO₃. In some embodiments, the chemical precursor solution can be one or more of NiFe₂O₄ or CoFe₂O₄. In some embodiments, the chemical precursor can be one or more of SiO₂, HfO₂, titania, zirconia, or doped precursors thereof. In an embodiment, the method can encompass one or more of these precursor solutions, or a solution comprising one or more mixtures of these precursor solutions.

The chemical precursor solutions can be selected such that the final nanostructured material displays valuable characteristics, or enhanced characteristics. For example, a compound might be selected to include a dopant added as part of the solute in the chemical precursor solution. Therefore, in some embodiments, the chemical precursor solution can be doped. Similarly, in another embodiment, the chemical precursor solution can comprise compounds that form a solid solution.

In the chemical precursor solution, the solvent can be any solvent that can evaporate or pyrolyze during the heat treatment of the infiltrated template. The solvent can also solubilize the solute of the chemical precursor. The solvent can also include solution stabilizers or modifiers. In an embodiment, the solvent can be water. In another embodiment, the solvent can be an organic, preferably a polar organic, including but limited to alcohols, ethers, amines, organic acids, polyhydroxyl compounds, polyethers, and polyamines, or compounds containing mixtures of these functional groups, and solvent mixtures thereof. In an embodiment, the solvent can be an ether-hydroxyl compound, such as for example 2-methoxy-ethanol. After infiltration, the infiltrated soft template can optionally be rinsed with the same solvent to remove residual precursor not inside the patterned portion of the template.

After infiltration, the infiltrated template can be heat treated to drive out remaining solvent, remove soft template and crystallize the chemical precursor to form the nanostructured material. In some embodiments, the heat treatment can have a first heat treatment and a second heat treatment. The first heat treatment can be a pyrolysis to remove the solvent from the chemical precursor solution. In some embodiments, the pyrolysis can be carried out at about 100° C. to about 450° C. for about 30 seconds to about 5 minutes. In another embodiment, the second heat treatment can be a thermal annealing to crystallize the precursor and remove the soft template, such as from about 600° C. to about 900° C. In an alternate embodiment, the thermal annealing can be a two-step heat crystallization process. In one embodiment, the anneal can be carried out from about 500° C. to about 700° C. and then increased to from about 700° C. to about 900° C. The increase can be immediate or, in an alternative embodiment the increase can ramp at from about 20° C./min to about 30° C./min. In another embodiment, the heat treatment step can be one step and carried out directly from about 500° C. to about 700° C. or from about 600° C. to about 900° C. In an embodiment, the thermal steps can be tailored to achieve the proper crystallization of the chemical precursor into the final composition that makes up the nanostructure. The thermal step can be conducted to crystallize the chemical precursor into a ferroic structure, preferably a ferroelectric structure. One of ordinary skill in the art would recognize that processing temperatures for various ferroic structures are known for different processing systems. For example, PZT in methoxyethanol can crystallize at around 650° C. to around 700° C., but other suitable heat treatments can exist for the same or different processing conditions.

The method disclosed herein can be tailored to control the thickness of a wall in a nanotube or nanotrench. Without wishing to be bound by theory, the component material of the precursor solution can have a smaller volume than the original solution after heat treatment, and as a result will adhere and/or crystallize with the sides and bottom of the template, leaving a hollow portion or center channel in the nanostructure. In an embodiment, the concentration of the chemical precursor solution can be adjusted to incorporate more or less of the chemical solute into the solution, such that a dilute solution would produce thinner walls as compared to a more concentrated solution. In another embodiment, the walls can be thickened by repeating the infiltrating step and the heat-treating. In alternative embodiments, the infiltrating step and the heat-treating step can be repeated such that the entire nanotube is completely filled, to form a nanopillar. Similarly, a nanotrench can be filled to form a nanowall.

In some embodiments, the top layer of the conformal layer can be removed via etching. In alternative embodiments, the top layer of the crystallized chemical precursor solution can be removed via etching. In some embodiments, both the top layer of the conformal layer and the top layer of the crystallized chemical precursor solution can be removed via etching. Alternatively, instead of or in addition to etching, an electrode can be deposited on top of the nanostructured material.

This nanomanufacturing approach can have a major advantage in ease of creation of user-defined size, shape, and location of the nanostructures, enabling fabrication of NEMS devices based on ferroelectric smart materials. Furthermore, this approach can be tailored for a variety of ceramic materials by appropriate choice of sol-gel precursors and processing temperatures. Finally, this nanomanufacturing method can be easily scaled for larger patterned areas, including but not limited to the use of nanoimprint lithography (NIL) instead of EBL for creation of the soft templates.

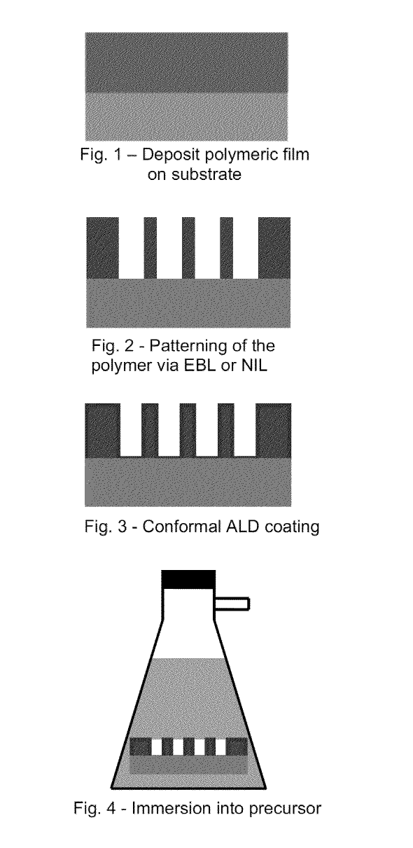

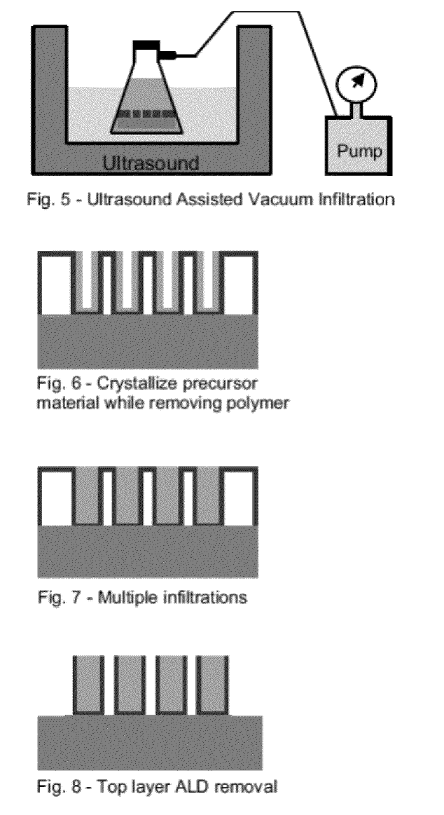

By way of example and not limitation, a method of fabricating nanostructured materials by use of polymeric templates can be described as a series of steps as follows. A thin or thick film of polymer (for example MicroChem Corporation ma-N₂₄O₃, MicroChem Corporation 950PMMA, and Zeon Corporation ZEP520) can be deposited by either spin or dip coating on a substrate capable of withstanding the processing temperatures required for the desired material. Examples of substrate include but are not limited to plain or coated Si wafers, fused quartz, or sapphire (FIG. 1). The excess solvent can then be removed via heat treatment at a temperature ranging typically from about 90° C. to about 150° C. for the appropriate amount of time, as defined by the vendor. The polymeric film can be patterned using electron beam lithography (EBL) or by mechanical pressure (nano-imprint lithography-NIL) using a pattern defined by the user (mask pattern for EBL; stamp for NIL). The thus-patterned polymeric film and substrate are hereafter referred to as soft-template (FIG. 2). The soft-template can be further coated with a thin (from about 10 nm to about 100 nm), conformal layer of metal, including but not limited to Pt or an oxide material, including but not limited to alumina (Al₂O₃) or titania (TiOₓ), which can be deposited via thermal- or plasma-enhanced-atomic layer deposition (ALD) (FIG. 3). A chemical solution precursor of the desired oxide material, (examples include but are not limited to: SiO₂, HfO₂, TiOₓ, doped and undoped PbZr₁₋ₓTiₓO₃ for x between and including 0 and 1, KNbO₃, Bi₄Ti₃O₁₂, SrTi₄Bi₄O₁₅, Na0.5Bi0.5TiO3, doped and undoped NiFe₂O₄, doped and undoped CoFe₂O₄, and (1-x)[Pb(Mg_{1/3} Nb_{2/3})O₃]-x[PbTiO₃] for x between and including 0 and 1) can then be infiltrated into the soft-template by immersion into a container of the chemical solution precursor (FIG. 4). The container and soft-template can be placed in an ultrasonic bath, and vacuum can be applied to the container to facilitate the infiltration. Vacuum levels can range from about 5 psi to about 75 psi and are adjusted for the specific polymer used (FIG. 5). After the completion of the infiltration i.e. when no more air bubbles are formed, the template can be removed from the bath and washed with solvent to remove excess precursor solution accumulated on the surface. The infiltrated template can then be heat-treated between about 100° C. to about 900° C. in one or more steps including but not limited to, hot plate, furnace/oven and/or rapid thermal processor for an amount of time customary for the crystallization of the material from the desired precursor. This step can be carried out to remove the solvents and organic material, including template, as well as to create the correct crystallographic phase of the desired material (FIG. 6).

The immersion of the template into the precursor along with subsequent heat treatment steps can be repeated multiple times to build-up the thickness of the desired material (FIG. 7). For example, depending of the aspect ratio of the pattern in the template and number of infiltration, nanopillars rather than nanotubes can be obtained. Optional physical etch (for example reactive ion etch (RIE) or inductively coupled plasma (ICP) can be performed to remove the top layer of ALD material and any eventual crystallized precursor solutions that are left-over on the top of the samples if free-standing structures are desired (FIG. 8). This method can allow creation of shapes and pattern in specific locations on the substrate, as well as creation of multiple shapes and aspect ratio of structures within the same sample.

In an embodiment, the steps of infiltrating and heat treating can be repeated. In other words, the steps of the sequence can be described as a first pass through the method, and then the product from the heat-treating step can be treated in a second pass through the method. For example, a nanostructured material can be prepared according to the method that can have a hollow center in the nanotube. The nanostructure can then be reimmersed in the chemical precursor solution and the chemical precursor solution infiltrated into the first nanostructured material in order to fill the nanotubes. The structure can then be rinsed and heat treated to form a second nanostructure. By this method, the nanotube can be filled in multiple steps to create a filled nanostructure. This structure can be described as a nanopillar. Alternatively, the method can be used to thicken the nanotube walls without completely filling in the nanostructure. In repeating this series of steps, the chemical precursor solution can preferably be the same in the second pass as in the first pass. Alternatively, the chemical precursor solution can be a different solution in the second pass versus the first pass. For example, a first precursor solution could infiltrate a coated soft template and the material heated to form a first nanostructured material wherein the middle of the nanostructure is hollow, i.e. a nanotube. Subsequently, a second precursor solution could infiltrate the nanotube, and the resulting heat treatment could produce a heterostructured nanotube or nanopillar. Different chemical complexes can then be achieved using the method, including for example, a magnetorestrictive composite and a piezoelectric composite that can produce magnetoelectrical behaviors.

In view of the method disclosed herein, a new category of materials can be prepared that have been previous unattainable in the art. By preparing these new materials, new properties and features that have not been experimentally demonstrated can now be accessed. Materials disclosed herein can have new architectures and structural features. Devices can now be prepared that utilize the new features and characteristics of the materials.

In an embodiment of the disclosure, a material can comprise a ferroic nanostructure. As used herein, a nanostructure is meant to indicate a structure having one or more dimensions on the nanometer scale, from about 1 nm to about 1000 nm, or from about 1 nm to about 500 nm. This scale would be in contrast to the microstructures, where the scale would include several microns in height. Note that the nanostructure referred to herein would represent the scale of a single nanostructure, typically its height and width. A grouping of nanostructures spread across the surface of a substrate could still be on the scale of microns, depending on how the user defines the pattern of structures, but the individual nanostructure would still have a height and width on the nanometer scale. Note that some nanostructures might also contain a length, as measured parallel the surface and perpendicular to the measured width, which could be on a micron scale. For example, a nanowall or a nanotrench could be created having nanometer scale heights and widths, but crafted across a surface for several microns.

The nanostructure can be any shape that one of ordinary skill in the art could prepare in a soft template. For example, a cylinder created in the surface of the soft template could yield a nanopillar or a nanotube. A nanotube could be present when the amount of chemical precursor is less than the amount necessary to completely fill the cylinder after heat treatment. As discussed above, the concentration of the chemical precursor in the chemical precursor solution can be designed to determine the final amount of solid in the nanostructure after heat treating. Other structures could include a nanowall; a nanotrench if the nanowall is hollow across an upper portion of the wall, a nanochannel if the nanowall is hollow in a center or lower portion; a conical shape; or other three-dimensional shapes, including three dimensional shapes prepared using a two photon lithographic process.

The relative size of a nanostructure can be described by a ratio known to one of ordinary skill as the aspect ratio. As used herein the aspect ratio is defined as the height of the nanostructure compared to the width of the structure. In the case of a cylinder in either a nanotube or a nanopillar, the width would be equivalent to the diameter, specifically the outer diameter. In the case of a shape with two unequal dimensions in the plane parallel to the substrate and perpendicular to the height, the width would be measured for the smaller of the two distances with the other distance being the length. For example a rectangular prism would have a height, and the smaller of the other two dimensions would be the width. Alternatively, a nanowall or a nanotrench could be described that would also have similar measurement so the rectangular prism. A height of the wall or channel and then a width of the wall or trench (outer wall widths.)

In an embodiment, the aspect ratio can be any aspect ratio greater than or equal to about 1:1, greater than or equal to about 1.1:1, greater than or equal to about 1.2:1 or greater than or equal to about 1.5:1. The aspect ratio can also be greater than or equal to about 2:1. In an embodiment, the aspect ratio can be from about 1:1 to about 100:1, 1:1 to about 50:1 or about 1:1 to about 20:1. The aspect ratio can be from about 1:1 to about 10:1, or from about 2:1 to about 5:1. The aspect ratio can also be greater than 1:1 to about 10:1, including greater than about 1.1:1 to about 10:1, great than about 1.2:1 to about 10:1, or greater than about 1.5:1 to about 10:1.

The height of the nanostructure can be equal to the height of the hole or pattern or space that was created initially in the soft template. The height of the nanostructure can be as high as approximately the original thickness of the soft template or soft template precursor. The height can also be shorter than the original thickness of the template or template precursor if part of the structure is removed by, for example etching or other techniques that remove the top portion of the nanostructure, or if shrinkage of the template during initial processing steps. In an embodiment, the height of the nanostructure can be at least about 20 nm, at least about 50 nm or at least about 100 nm. In an embodiment, the height of the nanostructure can be less than about 2000 nm, less than about 1500 nm or less than about 1000 nm. The height can be less than about 1000, nm less than about 900 nm, less than about 750 nm, or less than about 600 nm. In an embodiment, the height can be between about 10 nm and about 1000 nm, between about 500 nm and about 1000 nm, between about 100 nm and 1000 nm, or between about 150 nm about 1000 nm. In an embodiment, the height can be between about 100 to about 750, between about 150 nm to about 600 nm, or between about 150 nm and about 500 nm.

In an embodiment, the width of the nanostructure can be greater than or equal to about 10 nm, greater than or equal to about 20 nm, greater than or equal to about 30 nm, greater than or equal to about 50 nm, or greater than or equal to about 100 nm. The width of the nanostructure can be up to 1 micron. The width of the nanostructure can be less than or equal to about 500 nm, less than or equal to about 400 nm, or less than or equal to about 300 nm. In an embodiment, the width can be from about 30 nm to about 500 nm, about 50 to about 300 nm, from about 50 to about 250 nm.

Nanostructures of this disclosure can include hollow structures, such as nanotubes, nanotrenches or nanochannels. A hollow nanostructure can also then have a dimension for the thickness of the wall. The wall thickness can be tailored and controlled by the process disclosed herein such that narrow walls can be created. In an embodiment, the wall thickness of the nanostructure can be greater than or equal to about 5 nm, greater than or equal to about 10 nm, greater than or equal to about 15 nm, greater than or equal to about 20 nm, or greater than or equal to about 25 nm. In an embodiment, the wall thickness of the nanostructure can be less than or equal to about 500 nm, less than or equal to about 300 nm, less than or equal to about 250 nm, less than or equal to about 150 nm, or less than or equal to about 100 nm. In some embodiments, the wall thickness can be between about 5 nm and about 25 nm, or between about 5 nm and about 15 nm. The wall thickness can also be between about 5 nm and about 400 nm, between about 25 nm and about 300 nm or between about 50 and about 400 nm. The wall thickness can be tailored by the process in order to meet the desired application. For example, photocatalytic effects are largely enhanced on ferroelectrically active surfaces, and so structures made of ferroic nanotubes with wall thickness between 5 and 50 nm should show a large enhancement of photocatalytic response due to the large surface to volume ratio. Therefore, a nanotube with thin walls of about 5 nm to about 50 nm, or about 5 nm to about 15 nm, can be prepared for use in photocatalytic systems. In some embodiments, wall thickness can be less than approximately half the width of the nanostructure.

In view of the process disclosed herein and the materials and nanostructures disclosed herein, a large number of devices can be built that rely on nanostructured materials prepared and incorporating features of the disclosure set forth above. For example, devices that might rely on photonic and phononic crystals, terahertz emitters, energy harvesters, micromotors, micropumps, and nanoelectromechanical sensors, actuators, and transducers can be prepared utilizing the disclosure set forth above. In an embodiment, the device can contain a nanostructured material prepared by infiltrating a soft template with a chemical precursor solution and subsequently heat treating the infiltrated template to produce the nanostructured material. In an embodiment, the device can incorporate a ferroic material having aspect ratios and dimensions set forth above.

Reference will now be made in detail to specific aspects of the disclosed materials, compounds, compositions, articles, and methods, examples of which are illustrated in the accompanying Examples and Figures.

### EXAMPLES

### Example 1

A bottom-up nanomanufacturing method for fabrication of piezoelectrically-active, ferroelectric PbZr_{0.52} Ti_{0.48} O₃ (PZT) nanotubes with aspect ratios up to 5:1, based on vacuum infiltration of the precursor sol-gel solution into a polymeric template, created using electron beam lithography (EBL) is discussed below. This method can allow fabrication of ferroelectric nanostructures with user-defined shapes, location, and pattern variation across the same substrate.

Experimental Methods.

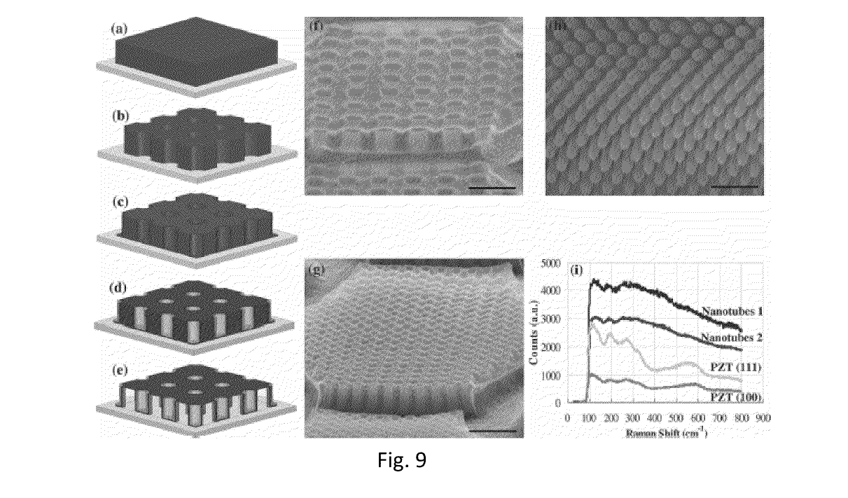

Fabrication of PZT nanotubes via soft-template infiltration can include two primary processing steps: (i) soft-template preparation and (ii) PZT infiltration. The soft-template was manufactured via spin-coating negative electron beam resist (e-resist) (FIG. 9a), subsequently patterned by electron beam lithography (FIG. 9b). After development, the polymeric template was coated with a thin layer of Al₂O₃ (<10 nm) via atomic layer deposition (ALD) (FIG. 9c) for mechanical consolidation. Next, the ALD-coated polymeric template was immersed into an ultrasound bath of PZT precursor sol-gel solution while under vacuum (FIG. 9d). After infiltration, excess PZT accumulated on the surface is removed via a rinse with solvent (2-methoxyethanol, 2-MOE). The sample is then pyrolyzed at 300° C. for 1 minute and annealed in a two-step crystallization process: the samples were placed in a furnace at 600° C.; the temperature was then increased to 800° C. at 25° C./min and held for 1 minute. Thermal annealing led to crystallization of PZT and decomposition of the organic resist, creating PZT nanotubes with a thin layer of Al₂ O₃ connecting adjacent tubes (FIG. 9e).

The height and width of the pattern in the resist (which ultimately determine the aspect ratio of the PZT structure) can be independently controlled. The height of the PZT nanotube was altered via varying the spin-coating deposition speed of the resist. The holes' lateral dimensions in the resist were defined via computer-aided drawings, which control the electron beam during patterning. Thus far, aspect ratios of 1.2:1 up to 5:1 have been produced (FIG. 9 f-h). More specific experimental methods are discussed below.

Soft-Template Processing.

(001)-cut Si substrates were used with an in-house-prepared bottom electrode stack, consisting of: 1 μm thick thermally grown SiO₂ as a Pb diffusion barrier; 200 Å of TiOₓ as an adhesion-promotion layer between the silicon dioxide and 1500 Å of Pt (both deposited via sputter deposition). The substrates were then cleaned with acetone, methanol, and isopropanol, followed by a dehydration bake for 10 min at 150° C. to improve resist adhesion.

Ma-N₂₄O₃™ (MicroChem™) was spun-coated onto a platinized silicon substrate with spin speeds ranging from 1000 rpm to 6000 rpm resulting in resist thicknesses from ˜500 nm to ˜220 nm, respectively. The resist thickness ultimately defined the maximum height of the PZT nanotubes. The resist was exposed using a JEOL JBX-9300FS system at 100 keV and 2 nA, and dose of ˜440±10 mJ/cm2 (optimized for various resist thicknesses) and developed via MF™-319 (Microposit™) for 70 s, followed by immersion in de-ionized water for 1 min.

The PZT precursor solution was prepared via a 2-methoxyethanol (2-MOE) solvent route, based on a method known in the art. The Pb[ZrₓTi₁₋ₓ]O₃ composition was targeted at the morphotropic phase boundary (x˜0.52), due to the expected enhancement of the ferroelectric and piezoelectric response at this composition. 10% excess Pb with respect to stoichiometric requirements was added to compensate for lead's high volatility at PZT crystallization temperatures.

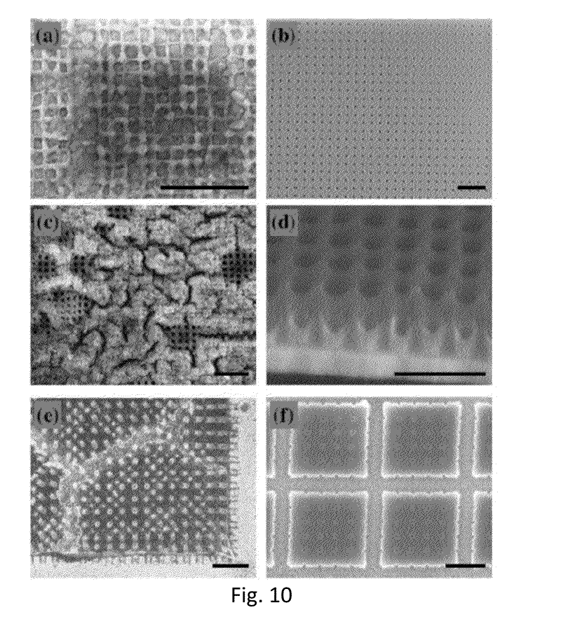

Critical processing steps for creating the PZT nanotubes included: 1) coating the polymeric template via ALD Al₂O₃; 2) implementation of vacuum infiltration; and 3) patterning the polymeric resist via a hierarchical scheme. In addition to offering a minimal mechanical consolidation for the template during the thermal treatment processes, the ALD-deposited Al₂O₃ layer also acted as a chemical barrier and prohibited reactions between the PZT precursor and the e-resist. In absence of the Al₂O₃ layer, a strong chemical reaction was observed between the organic template and the PZT precursor, even prior to the thermal treatment (FIG. 10a). This chemical reaction was avoided by using the thin (˜10 nm thick) Al₂O₃ layer (deposited via a Cambridge Fiji ALD System) (FIG. 10b). ALD was chosen over other deposition techniques due to excellent thickness control over complex landscape profiles 10 nm was the lower boundary for the ALD layer thickness as thinner films resulted in loss of pattern definition (i.e. ripples were observed in regions between consecutive tubes and the tubes buckled). Thicker layers of Al₂O₃ resulted in an increased and undesired voltage drop when performing PFM measurements. In addition, as the thickness of the ALD layer increased the through-pinholes' concentration decreased. The through-pinholes provide means for organic byproduct removal during thermal decomposition. The ALD processing temperature was set at ˜100° C. to prevent early thermal deterioration of the e-resist. Lower processing temperatures are undesirable due to increased cycle time required for the chemical reactions between water and the Al precursor (trimethylaluminum, TMA) for Al₂O₃ layer formation.

In order to aid the PZT precursor infiltration of the templates, the infiltration was performed under vacuum; however, PZT precursor accumulation on the template surface was observed (FIG. 10c). This is possibly due to a superhydrophobic behavior of the submicron-patterned surface. In order to overcome this issue, the templates were immersed in the PZT precursor solution under vacuum and then placed in an ultrasonic bath. Cross-sections of the resulting PZT structures were prepared via focused-ion beam (FIB) milling and imaged via a FEI Nova Nanolab 200 FIB/SEM. With the aid of the ultrasonic bath, the precursor solution infiltrated into the template, overcoming the surface and capillary forces, creating cup-shaped structures of PZT within each hole (FIG. 10d).

In samples with a large patterned area (50 μm×50 μm), delamination and cracking were often observed after thermal treatment (FIG. 10e). Organic decomposition of the soft-template during the high temperature anneal, in addition to ferroelectric distortion at the Curie temperature, and thermal expansion coefficient mismatch between PZT, Al₂O₃, and the substrate can lead to creation of residual stresses in the nanostructures. While in thin films, these stresses are distributed, in the patterned nanostructures, the stresses can become highly localized, leading to delamination and cracking. Observation of the cracking patterns identified the presence of a natural stress-accumulation/release length scale, ultimately leading to the redesign of the polymeric templates' pattern. Gaps were added between patterned features, at similar distances as the previously observed critical stress-release length scale, resulting in a hierarchical pattern (FIG. 10f).

Raman Spectroscopy.

The crystallographic structure of the nanotubes was verified via micro-Raman spectroscopy with an exposure wavelength of 512 nm. Reference PZT films with a thickness similar to the tubes' height were spun-coated using the same sol-gel precursor and similar thermal profiles as used in the fabrication of the nanotubes. The PZT thin films were phase-verified via an X′Pert PRO Alpha-1 at 45 kV and 40 mA with a Johansson monochromator and ultra-fast X′Celerator detector: no other peaks but those related to the perovskite phase or substrate were observed in the X-ray diffraction patterns.

Switching Spectroscopy Piezoelectric Force Microscopy (SS-PFM).

The ferroelectric nature of the PZT nanotubes was characterized via Switching Spectroscopy-PFM (SS-PFM), a method known in the art. SS-PFM was performed using a platinum coated AFM tip (Olympus, AC240™, Electri-lever) as the top electrode, while the underlying platinized silicon substrate was used as ground (i.e. bottom electrode). Electromechanical hysteresis loops were acquired at each scanned point on a closely messed grid via the application of a triangular wave of DC pulse steps (i.e. bias). The bias was applied to the sample through the AFM tip, and the response (amplitude and phase) were collected after each DC pulse for a band of frequencies. The change in response amplitude (A) and phase (f) was used to determine the piezoelectric response [PR=Asin(f)].

Finite Element Modeling.

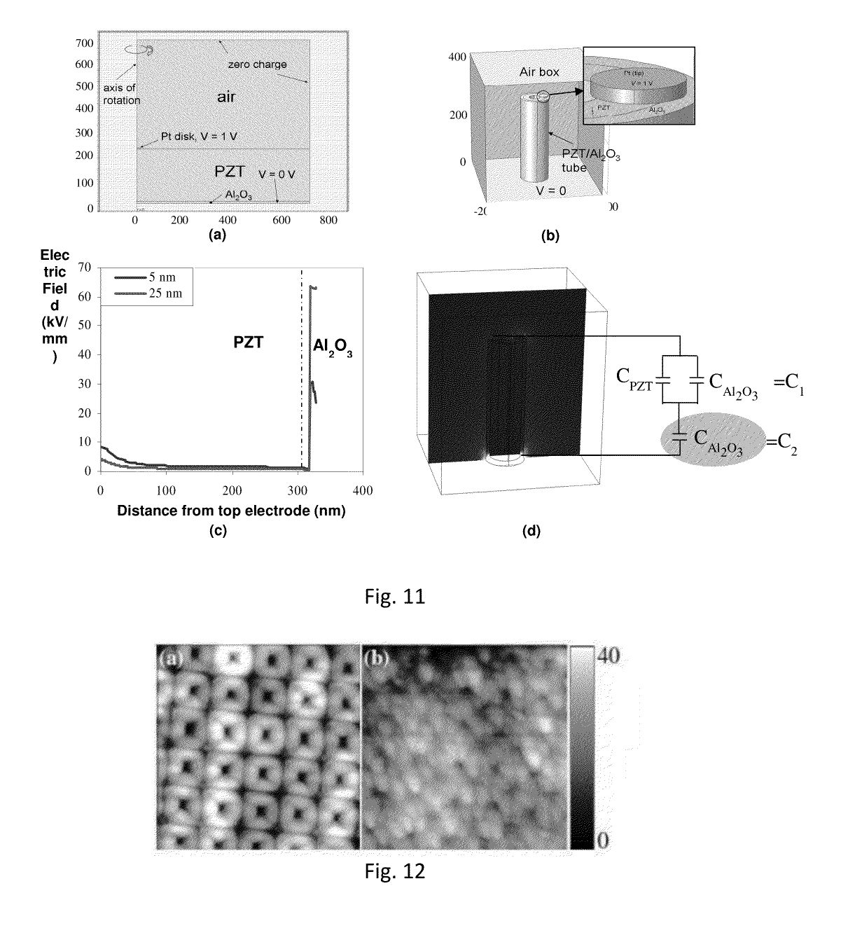

COMSOL Multiphysics® (v.4.2) finite element modeling of the nanostructure and reference thin films was used in order to simulate electric field distributions in presence of a thin layer of Al₂O₃ (=12), in addition to the ferroelectric phase (PZT,=750), with a large bottom electrode and a very small top electrode representing an AFM tip. The model geometries for an Al₂O₃/PZT nanotube and a PZT film are shown in FIG. 11a,-b. The AFM tip was modeled as a 30 nm diameter Pt disk. Its potential was set to V=1 V. Boundary conditions at the bottom surfaces of the models were set to zero potential (to describe bottom electrodes, i.e. platinized silicon substrates). Boundary conditions along the other outer boundaries of the models were set to zero charge.

The same model was also used to study the effects of the PZT wall thickness variation on the electric field drop within the full height of the nanotubes. The results are shown in FIG. 11c. It is clear that a reduction in PZT wall thickness leads also to a large reduction of the electric field in the immediate proximity of the AFM tip (top electrode). The PZT and Al₂O₃ layers within the length of the tube work effectively as voltage dividers (capacitors in parallel), while the Al₂O₃ layer in direct contact with the bottom electrode works (FIG. 11d) as an in series capacitor, causing a large voltage drop in both thin and thick PZT-walled nanotubes. With increase in PZT wall thickness, the capacitance associated with the PZT (C_{PZT}) is increased. Therefore, the voltage (and field) drop across the C1 (tube height) are smaller.

Nonlinear Measurements.

Nonlinear electromechanical measurements were performed for samples with varying PZT nanotube wall thickness, in a 500 nm×500 nm area with a 40×40 grid (1600 total strain vs. voltage curves). The max AC voltage applied was 9.5 V p-p (less than ⅓ the coercive voltage, in order to ensure the domain wall distribution was maintained unaltered). The strain-amplitude response was approximated as a second-order polynomial function. The fit parameters were then averaged over the 40×40 grid. When possible, only data with R2 value 0.8 were used. Differentiation of the strain amplitude response vs. electric field yielded the Rayleigh parameters. In order to quantitatively compare the nonlinear response of PZT nanotubes and films, all voltage values were transformed into electric field: the FE modeling results were used for this conversion.

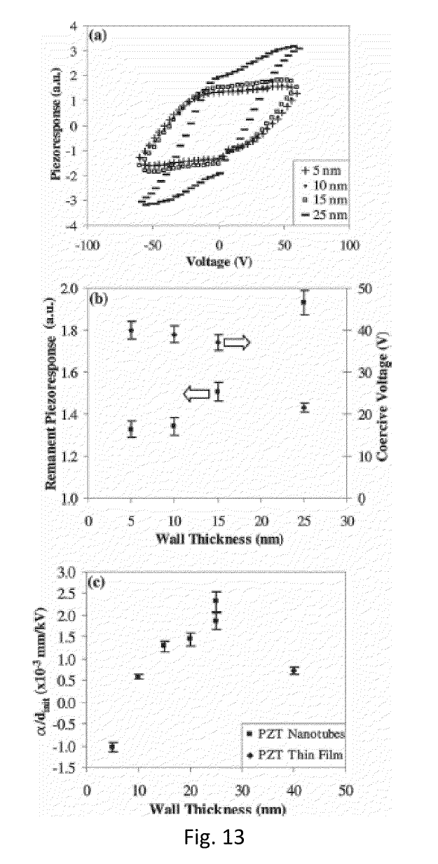

At PZT tube wall thickness 25 nm, grain growth on top of the PZT nanotubes (FIG. 12a) was observed, altering the effective height and thus the effective electric field. Therefore, the effective electric field was appropriately corrected by a 20 nm increase in the height of the tube (approximate PZT grain size). FIG. 13 shows the piezoelectric nonlinear properties at 25 nm thickness calculated in presence and absence of electric field adjustment.

Characterization of the Nanotubes.

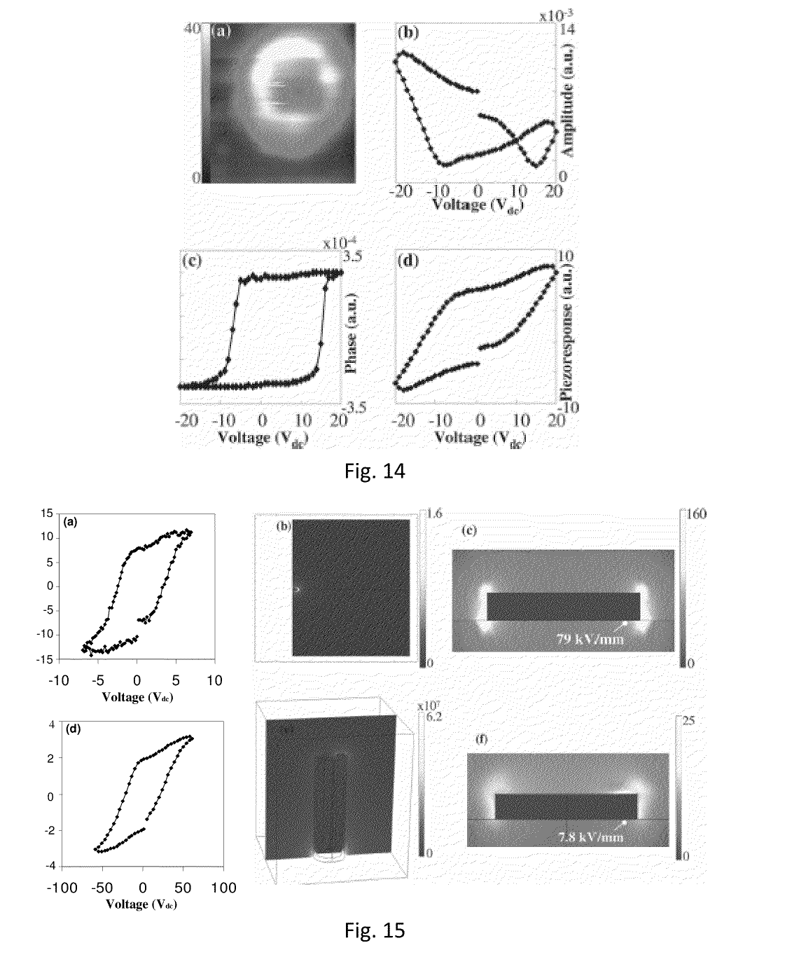

The crystallographic structure of the PZT nanotubes was characterized by micro-Raman spectroscopy (FIG. 9i). Spectra from 270 nm-thick PZT thin films (similar thickness to PZT nanotubes' heights and phase-verified via x-ray diffraction) were used for reference. The ferroelectric nature of the nanotubes was determined by switching spectroscopy-PFM (SS-PFM), in which electromechanical hysteresis loops were collected by measuring the PFM amplitude and phase of a single PZT nanotube after applying DC bias in a triangular waveform (FIG. 14a-d). The change in amplitude (A) and phase (Ö) at resonance after each applied DC bias are a direct result of the nucleation and growth of domains. The amplitude and phase were recorded after DC bias removal to avoid complications associated with the DC bias dependence of the piezoelectric response as a large enough DC bias can stabilize the domains configuration. The electromechanical response of the tubes showed a typical butterfly-like shape and the phase saturated, corresponding to ˜180° switching. The above observations, in addition to a saturated hysteretic piezoresponse, suggest switching (i.e., ferroelectric) behavior. The asymmetry observed in the butterfly loops is a clear indication of internal bias, which is possibly due to dissimilar boundary conditions between top and bottom electrodes. SS-PFM data was also collected for reference templates simply coated with Al₂O₃ (without PZT). No hysteretic response was observed in these electromechanical measurements, thus suggesting that the measured response for the PZT tube is due to the converse piezoelectric effect and not electrostriction or geometric anomalies. Note also that due to the tip radius size's (˜10 nm) similarity to the probed thickness, the “measured” nanotubes' thickness is much larger than the actual nanotubes thickness. Effectively the PFM results are based mostly on lateral contact between the AFM tip and the nanotubes' internal walls. However, it is expected for this contact to be mostly in the upper surface of the tubes rather than in an inside-tube location. The stability of contact is indeed consistent with the stable topographic images observed (See FIG. 12).

SS-PFM piezoresponse of PZT nanotubes were also compared to those collected from PZT films with thickness similar to the height of the PZT nanotubes (FIG. 15a). The PZT films were manufactured with the same PZT precursor sol-gel solution and similar thermal profiles as the nanotubes. The films were deposited on a platinized silicon substrate coated with 10 nm of atomic layer deposited Al₂O₃ in order to emulate a similar bottom electrode stack as the PZT nanotubes. The measured coercive voltage of the PZT film was nearly one order of magnitude lower than that of the PZT nanotubes (FIG. 15d). Previous studies have shown that the presence of a low-permittivity layer, such as impurities, between the PFM tip and the ferroelectric material can result into a lowered effective electric field in the ferroelectric. However, as the low-permittivity Al₂O₃ is present in the material stacks in both thin film and nanotube configurations, the origin of such a large variation in the coercive voltage need to be sought elsewhere.

In order to study the electric field distribution through the structure with a very localized top electrode (AFM conductive tip), finite element modeling (FEM, via Comsol Multiphysics) of the electric field distributions were performed for the PZT thin film and nanotube configurations (FIG. 15 b-c, e-f, respectively). The large field enhancement observed at the edges of the disk representing the AFM tip can be discarded as a geometric artifact of the model as real AFM tips lack sharp edges; however, values of the electric field somewhat away from the sharp edges of the disk electrode can be meaningfully compared for the two configurations. The electric field distribution in the PZT nanotube showed a sharp drop of electric potential across the Al₂O₃ layer at the bottom of the nanotube, with the electric field mostly concentrated in that part of the structure (FIG. 15e). This electric field-concentration in the Al₂O₃ layer for the nanotubes is due to the dramatic difference in the relative dielectric permitivities of the PZT (∈ᵣ=750) and alumina (∈ᵣ=12). For the PZT thin films, no such field enhancement in the alumina layer takes place due to the film's infinite lateral dimension (FIG. 15b).

During the SS-PFM scans, the electric field created in the ferroelectric materials in contact with the PFM tip's apex is responsible for nucleation of domains with opposite polarization. From the FEM results, it is clear that for the same applied voltage, the resulting electric field underneath the tip's apex in the PZT films (79 kV/mm) is approximately 10 times larger than in the PZT nanotubes (7.8 kV/mm) (FIG. 15c,f). This is in excellent agreement with the experimental SS-PFM results that show an order of magnitude increase in the required switching voltage for the PZT nanotubes compared to the PZT films (20 V and 2 V, respectively).

In order to study ferroelectric size effects, SS-PFM data were also collected for PZT nanotubes with wall thickness ranging from 5 nm to 25 nm. The nanotubes' wall thickness was varied by increasing the number of sol-gel infiltrations, while the overall aspect ratio of the structures was kept constant at 5:1. A high aspect ratio was chosen in order to minimize substrate clamping effects. FIG. 13a shows the piezoresponse as a function of tube thickness. As the tube thickness increased, the remnant piezoresponse increased and the coercive voltage decreased (FIG. 13b).

In considering the dependence of response on tube diameter, it is germane to analyze the PFM image formation mechanism in these structures. The PFM measurements detect the surface displacement of the material induced by bias applied to the conductive tip. The latter, in turn, are determined both by the localization of electric field induced by the tip, and the strain response of the material (i.e., the corresponding Green's function). In the thin film geometry, for tip electrode PFM the electric potential drop is −1/r for distances r>a, where a is tip-surface contact radius that can be determined self-consistently from topographic images. The corresponding Green's function generally decays as 1/r as well, giving rise to strong localization of the electric field below the probe on the distances comparable to contact radius. For top electrode setup (e.g. PFM on capacitors), the field is uniform and the strain response falls on the length scale of film thickness (hence the resolution of PFM on capacitors is proportional to film thickness). For the tube geometry, potential drop exists along the length of the PZT nanotube (as illustrated below) and the effect of field concentration below the probe is much less pronounced than for the tip-electrode setup in the case of thin films. At the same time, the tubes are significantly less clamped than thin films in the either tip-electrode or top-electrode case. Combination of these two factors suggests that the probing volume in PFM is strongly extended along the tube lengths. Hence, multiple grains and domain walls will contribute to the response, giving rise to this averaged behavior.

The decrease in the remnant piezoresponse and increase in the coercive voltage with decreasing wall thickness could be potentially due to changes in the electric field distribution underneath the AFM tip as a function of wall thickness. However, finite element modeling of the electric field distribution shows that the same voltage translates into a smaller electric field in the PZT nanotube under the AFM tip for the thicker-walled structures. Unlike the classical work exploring effects of the ferroelectric “dead” layer on polarization or hysteresis loop in thin films (where film and dead layer are effectively connected sequentially, as capacitors in series), here, the PZT tube, the outer alumina layer, and air are connected in parallel. This means that, due to the electrostatic field drop, higher coercive voltages should be required to switch the overall polarization of the material as the wall thickness increases, since the effective capacitance associated with the tube wall will be larger, with an increased voltage drop through the bottom alumina layer. However, this result is inconsistent with the observed trend, which shows a reduction in the coercive voltage as the wall thickness increased. Thus, another mechanism, affected by the PZT tube thickness, is responsible for the observed trend. Specifically, variations in extrinsic contributions due to the modification of either the population or mobility of the internal interfaces (phase boundaries and domain walls) with a change in length scales should be considered.

With a reduction in the critical dimensions of the ferroelectric phase (i.e., wall thickness), progressively finer domain structures are expected until a critical ferroelectric thickness is reached, at ˜10 nm (FIG. 13b). At the (extrinsic) critical thickness, the overall energy of the system cannot be further reduced by creation of non-180° domain walls, and therefore the formation of non-180° domains is no longer energetically favorable. The absence of non-180° domain walls will lead not only to a reduced piezoresponse by reduction of the extrinsic contributions but will also lead to an increase in the coercive voltage. Such critical thickness for ferroelectric materials have been previously studied theoretically and estimated at ˜10 nm for PbTiO₃. Experimental observations in ferroelectric films have also shown such critical size effects, which however have been limited to much larger values: ˜60 nm for PbTiO₃ thin films on (001) LaAlO₃ substrates, ˜50 nm for PbTiO₃ thin films on (001) SrTiO₃ substrates, and ˜60 nm for Pb(Zr_{0.53} Ti_{0.47})O₃ on platinized Si wafers. However, the results from thin films are in part convoluted with the effects of lateral constraints of thin films and residual stresses formed at cooling from processing temperatures. The values observed in the free-standing PZT nanotubes are in excellent agreement with the theoretical studies, which indeed exclude residual stress effects and lateral constraints.

The continuous increase in the remnant piezoresponse at wall thicknesses>10 nm is also in part attributed to an increased grain size in the nanotubes. An increase in the grain size can contribute to piezoelectric response through extrinsic effects, as indeed both domain density and domain wall mobility are affected by grain size. As the size of the ferroic phase (i.e., grain size) increases, the concentration of grain boundaries decreases. Grain boundaries can act as pinning sites for internal interface motion. Therefore, a reduction in concentration of grain boundaries can translate into an increase in domain wall mobility. Thus, grain growth can result in an increase in non-180° domain population and mobility, which ultimately leads to the increase in the remnant piezoresponse and saturation through extrinsic contributions.

The reduction in coercive field with decreasing wall thickness can also be explained by reduction in density and ultimately absence of non-180° domain walls at critical length scales. Although switching can occur via 180° reorientation of polarization, experimental and theoretical studies over the last decade have suggested that switching occurs by reorientations of dipoles through an intermediate non-180° “rotation”. This mechanism of switching, rather than the direct 180° rotation, is believed to be more energetically favorable. If the formation of non-180° domain walls in energetically unfavorable at room temperature (without externally applied electric field but in presence of only thermal energy), it is also quite probable that similarly under applied electric field, a larger amount of electrical energy would be required for the onset of switching through intermediate non-180° polarization rotation. This implies that either a higher amount of energy is required for polarization switching events in nanotubes with thinner PZT walls, as the non-180° requires a higher energy threshold or otherwise that the switching will need to happen through direct 180° rotation. Therefore, in the nanotubes with critical dimension, i.e., thickness, below the critical size, switching will requires higher energies and therefore higher coercive fields.

In order to further quantify extrinsic contributions to the piezoelectric response as a function of tube thickness, non-linear PFM measurements were performed and analyzed using the Rayleigh Law. The Rayleigh Law applied to ferroelectrics describes their electromechanical response in sub-switching conditions: the piezoelectric coefficient can be expressed as linearly dependent on the applied electric field's amplitude: d=dᵢₙᵢₜ+aE₀. dᵢₙᵢₜ represents the field-independent piezoresponse components which are dominant at low fields: these are due to intrinsic ionic response as well as extrinsic contributions from reversible domain wall vibration and motion. a represents extrinsic contributions through irreversible motion of domain walls or phase boundaries. The ratio of the Rayleigh parameters a/dᵢₙᵢₜ is used as a quantitative measure of the extrinsic contributions to the piezoelectric response, under the assumption that the reversible extrinsic contributions are limited with respect to intrinsic contributions. FIG. 13c shows the ratio of the irreversible to reversible Rayleigh parameters as a function of wall thickness. For wall thicknesses below 10 nm the a/dᵢₙᵢₜ ratio is close to null, which indicates negligible irreversible extrinsic contributions to the piezoelectric response in these samples. At increasing wall thickness (from 15 to 25 nm), the Rayleigh parameters' ratio increased, thus identifying a significant enhancement of domain wall motion contribution to the piezoelectric response.

For reference, the reversible to irreversible Rayleigh parameters' ratio was also determined for PZT thin films with similar thickness as the PZT nanotube walls (the film's minimum thickness is limited by the maximum possible spin-coating speed and the molarity of the precursor solution). The PZT films were deposited on platinized substrates coated with 10 nm ALD Al₂O₃, (similar stack configuration as the electric field study). SS-PFM hysteresis loops and Rayleigh-like nonlinear behavior were observed only for PZT films with thicknesses>40 nm (shown in FIG. 13c). The Rayleigh parameters' ratio is substantially larger in the PZT nanotubes than the PZT films confirming a substantial increase in extrinsic piezoelectric response in PZT nanotubes due to reduction of lateral and substrate clamping effects on domain wall motion in the high aspect-ratio nanotubes.

In summary, free-standing PbZr_{0.52}Ti_{0.48}O₃ (PZT) nano tubes were fabricated on platinized Si wafers with aspect ratios up to 5:1. Utilizing standard e-beam lithography, a polymeric template was created and infiltrated under vacuum by the PZT sol-gel precursor. Coating the polymeric template with a thin layer of Al₂O₃ via ALD prior to PZT immersion, prevented chemical reactions between the PZT precursor solution and polymeric template. The organic soft-template thermally decomposed during the ferroelectric material's crystallization, resulting in minimal residual stresses in the PZT nanotubes. Reduced residual stresses, in addition to minimal lateral and substrate constraint, led to a substantially larger amount of extrinsic contributions to the piezoelectric response of the PZT nanotubes compared to PZT thin films of similar stack configuration and thickness. Furthermore, the extrinsic critical thickness (i.e., critical length scale above which ferroelastic domain formation is energetically favorable) in PZT nanotubes was in superior agreement with previous theoretical predictions with respect to critical thickness experimentally observed in thin films.

### Example 2

The characterization of high aspect ratio PZT nano-structures by leveraging band excitation piezoresponse force microscopy (BE-PFM) is discussed below.

Experimental Methods.

PZT nanotubes were fabricated leveraging vacuum infiltration of a precursor Pb_{1.1}Zr_{0.52}Ti_{0.48}O₃ solution into a soft-template. To create the soft-templates, negative electron-sensitive resist was spun-coated onto a platinized silicon wafer, and patterned using electron beam lithography. The soft-templates were then coated with a thin layer (<10 nm thick) of Al₂O₃ by atomic layer deposition (ALD). The template was then immersed into an ultrasound bath of PZT precursor solution while under vacuum. Once infiltration had been completed, the template was removed from the bath, squirt-rinsed to remove excess PZT on the surface, pyrolyzed, and subsequently annealed. Thermal annealing led to decomposition of the organic template and simultaneous crystallization of PZT. A detailed description the PZT nanotube manufacturing procedure is described above

The converse piezoelectric effect for the PZT nanotubes was qualitatively characterized via band excitation piezoelectric force microscopy. BE-PFM was performed on virgin samples, using the platinized substrate as bottom electrode (ground), while probing the top of the PZT nanotubes with a platinum-coated AFM tip (Olympus, AC240™, Electri-lever). For all scans, the resonance frequency of the system (tip and sample) was set as the center frequency of the excitation frequency band such that regardless of the scanned region the resonance frequency fell within the probing bandwidth.

The ferroelectric nature of the nanotubes was studied via switching spectroscopy piezoelectric force microscopy (SS-PFM). Electromechanical hysteresis loops were collected at each scanned point on a closely meshed grid. A triangular wave of electric DC steps from −20 V to 20 V was applied to the sample, and the sample's response was collected after each pulse for a band of frequencies.

Results and Discussion.

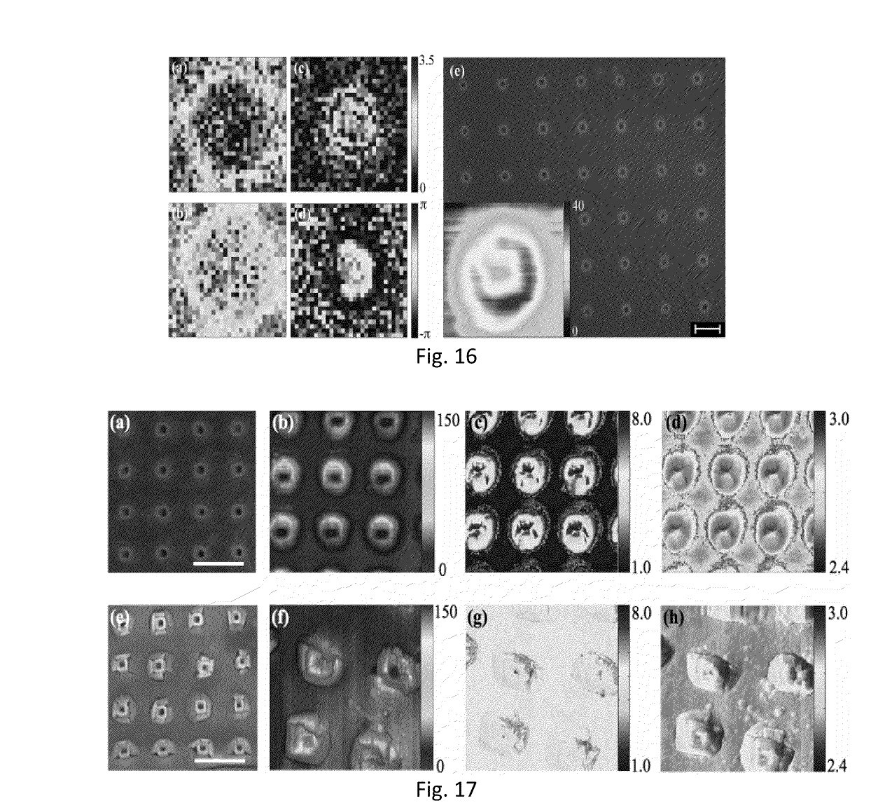

In PFM scans, an AC voltage is applied between the conductive tip, in contact with the probed material, and a bottom electrode also in contact with the sample. The application of the time varying voltage results in an oscillating surface displacement due to the converse piezoelectric effect, which ultimately results in the cantilever being driven into oscillation. If the driving frequency of the PFM signal approaches the contact resonance of the system (i.e., cantilever and sample), then the recorded deflection of the cantilever can increase by orders of magnitude, resulting in an increase in sensitivity (i.e., increase in signal-to-noise ratio). In the high aspect ratio PZT nanostructures considered in this work, the topographical variations, in addition to the active nature of the PZT vs. the inactive nature of the alumina layer, led to large variations in the contact resonance frequency of the system. A direct effect of such large frequency variations is that the study of the PFM response at a single frequency would result in a misrepresentation of the actual piezoresponse of the nanostructures. FIG. 16 shows the PFM amplitude of a single, 100 nm-wide, PZT nanotube as measured at 255 and 267 kHz. The locations corresponding to the highest amplitude of piezoresponse are clearly different in the two measurements: while in the lower frequency case, they correspond to an area larger than the nanotube cross-section, at higher frequency, they mostly correspond to the tube thickness. It is also noteworthy that the background noise level is also dependent on the scan frequency and therefore, a change in frequency can easily lead to reduction of acquired information.

To maintain a large signal-to-noise ratio throughout a scanned region of active and inactive material, BE-PFM was used. BE-PFM allows deconvolution of the piezoresponse from the excitation frequency by collecting the response at the specific resonance frequency for each point in a scanned area, leading to a more accurate characterization of the material.

FIG. 17 a-d show the BE-PFM response of an array of PZT nanotubes with 100 nm outer diameter, 4:1 height to width aspect ratio, and approximate PZT tube thickness of 10 nm, connected by a continuous 9 nm-thick alumina layer between the top surface of adjacent PZT nanotubes. The amplitude of the PFM response on a PZT nanotube (FIG. 17c) was 8 times larger than on the suspended alumina film, with the maximum response registered on the inner portion of the tube. The local increase in PFM amplitude response (FIG. 17c) on the upper half of the nanotubes corresponds to the regions where the topography (FIG. 17b) is also slightly higher. Although topography overestimations due to large height variations are quite common in AFM measurements, such is not the case for these samples. The AFM topography scan was indeed performed from left to right (i.e., horizontal direction) in FIG. 17b and the asymmetry in the tube height was observed along the vertical direction in the scanned region (top to bottom in the figure). Thus, the increase in the PFM response is likely due to slightly thicker walls on one side of the tubes compared to the other. Such thickness variations within a single tube are possible if the extraction of the samples from the PZT bath and their subsequent thermal treatment were performed on not flat surfaces (such as the substrates leaning against a crucible boat).

It is interesting to note that the frequency plot (FIG. 17d) shows ˜60 kHz variation in the resonance frequency on the scanned region. This underlines once more the importance of performing the PFM measurements in a band excitation configuration rather than at a single resonance frequency.

The BE-PFM response for semi free standing nanotubes with similar diameter, aspect ratio, and tube thickness (to the nanotubes in FIG. 17 a-d) is shown in FIG. 17 e-h. These nanotubes were “released” from the Al₂O₃ film due to cracking around the top outer edge of the nanotubes, specifically at the corners of each nanotube. Such cracking locations are consistent with stress concentration regions: higher than average stress can develop in the samples if the surface PZT is not completely removed during the solvent-rinse step. The resulting Al₂O₃/PZT thin film bilayers can then lead to creation of large residual stresses due to the thermal expansion coefficient mismatch between PZT and Al₂O₃ when cooling from the high processing temperatures. Presence of excess surface PZT is also consistent with the relatively large PFM response registered in the regions between adjacent PZT nanotubes in these samples (FIG. 17f).

For the semi-free-standing nanotubes, as opposed to the PZT nanotubes connected by the thin alumina layer, the maximum PFM response was recorded at the outer edge of the tubes. Intriguingly, the topography was underestimated in the same regions by the AFM. It is probable that the two effects (underestimated topography and large piezoelectric response on the outer edge of the nanotubes) are correlated and caused by the AFM tip pushing through the cracks on the PZT/Al₂O₃ layer, and becoming entrapped in the crack in the proximity of the nanotube. As the tip then attempts to ascend the steep side-wall of the tube, the force of the AFM tip causes the tube to bend, resulting in a “registered” reduced topography, and possibly a larger contact area between the tip and the slightly bent tube. The improved contact could effectively translate into a reduction of the voltage drop at the tip-to-sample junction and ultimately result in a higher piezoelectric response, due to an increased local electric field in the PZT nanotube. As the tip then traces across the tube thickness, the nanotube unbends, returning to its original shape. The PFM response then returns to a lower value at the “center” of the nanotube.

It is noteworthy that although the overall piezoresponse recorded at the geometrical center of the nanotubes is much smaller than on locations corresponding to the walls and thickness, the response is never quite “zero.” This is mostly due to the inability of the atomic force microscope to fully penetrate the nanotubes with high aspect ratio. In fact, although scanning electron microscopy measurements show that the overall length of the nanotubes is approximately 400 nm, the topography as measured by AFM shows nanotube heights well below half this value (150 nm or less, see FIG. 17 b,f)

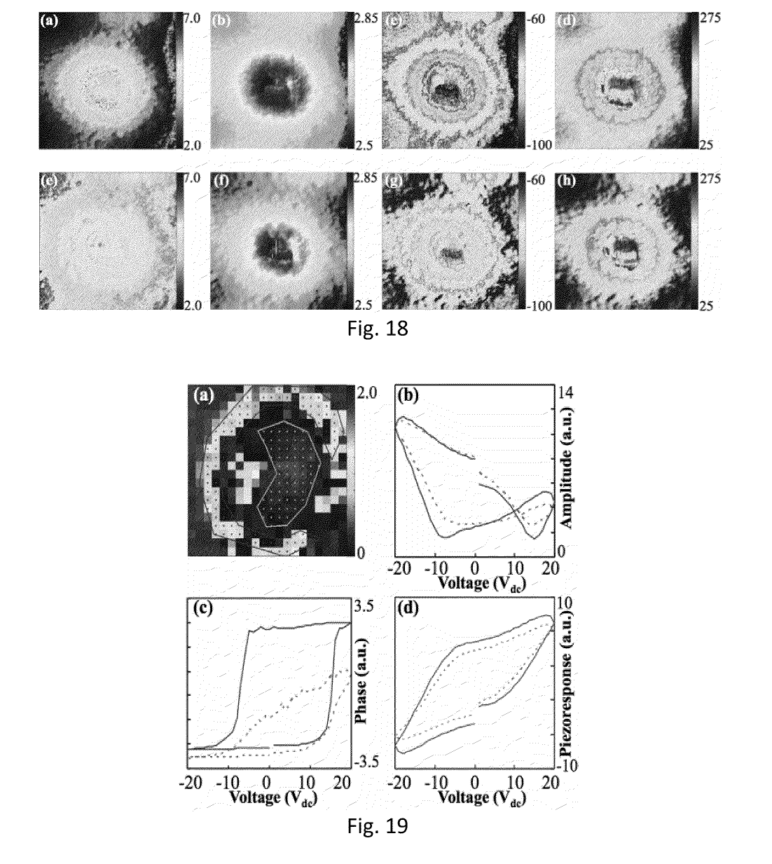

The ferroelectric nature of the nanotubes was also verified by write and read experiments. The samples' surface was first scanned with positive or negative DC voltages (+15 V and −15V, respectively). The BE-PFM amplitude response was then recorded after each applied bias scan (FIG. 18 a-h). The resonance frequency (FIG. 18 b,f) and quality factor (FIG. 18 d,h) remained substantially unchanged, while the amplitude (FIG. 18 a,e) and phase (FIG. 18 c,g) of the PFM response showed a clear change with the sign of the applied write (i.e., “poling”) voltage. An invariable resonance frequency and quality factor is indeed expected, as these parameters are mostly governed by the electromechanics of contact between the AFM tip and the sample, as well as the topography of the sample itself. The variation of the PFM amplitude and less than complete 1800 phase switching with the sign of the write voltage could indicate either the presence of a strong internal bias in the PZT nanotube or simply that the applied voltage was below the requirements for reaching saturation. Indeed, for an ideal sample at saturation, the amplitude of the PFM response should be identical for positive and negative voltages.

Electromechanical hysteresis loops were collected by measuring the BE-PFM amplitude and phase response of single PZT nanotubes, after applying DC bias in a triangular waveform (FIG. 19 a-d). The changes in amplitude and phase at resonance after each applied DC bias are a direct result of the nucleation and growth of domains. The phase and amplitude were recorded after DC bias removal to avoid complications associated with the DC bias dependence of the piezoelectric response, as a large enough DC bias can stabilize the domains configuration.

The average phase, amplitude, and piezoresponse were determined for the on-tube and inside-tube locations. The on-tube locations showed better-defined butterfly-loop curves compared to inside-tube locations (FIG. 19b).

The phase also showed clear saturation for on-tube locations (FIG. 19c). The above observations, in addition to a saturated hysteretic piezoresponse (FIG. 19d), suggest switching (i.e., ferroelectric) behavior for the on-tube locations. It is also noteworthy to add that the presence of a butterfly-shaped strain-voltage curve for the inside tube locations is consistent with a quasi-continuous contact between the AFM tip and the tube wall across the scanned area. As mentioned earlier, large-area AFM scans of the topography showed that the AFM tip is not capable of complete tracking of the features, and cannot fully penetrate the nanotubes. The observed butterfly-loop piezoelectric response for the location “inside the nanotube” is therefore mostly a measure of the piezoelectric excitation with lateral contact of the AFM tip to the nanotubes.

In summary, PbZr_{0.52}Ti_{0.48}O₃ (PZT) nanotubes with 4:1 aspect ratio and 100 nm outer diameter were characterized by BE-PFM. Characterization of the piezoresponse of the high aspect ratio PZT nanostructures via BE-PFM allowed to overcome the misrepresentations of the response observed when using single frequency PFM. The PZT nanotubes exhibited ferroelectric behavior as evidenced by saturated piezoresponse hysteresis loops and phase switching. Additionally, challenges and artifacts associated with PFM characterization of alumina-connected vs. semi-freestanding nanotubes were discussed.

### Example 3

The effects of lateral and substrate constraint on the piezoelectric response of PbZr_{0.52}Ti_{0.48}O₃ nanotubes by controlling the medium surrounding the nanotubes and the tube's aspect ratio, respectively are discussed below.

Experimental Methods.

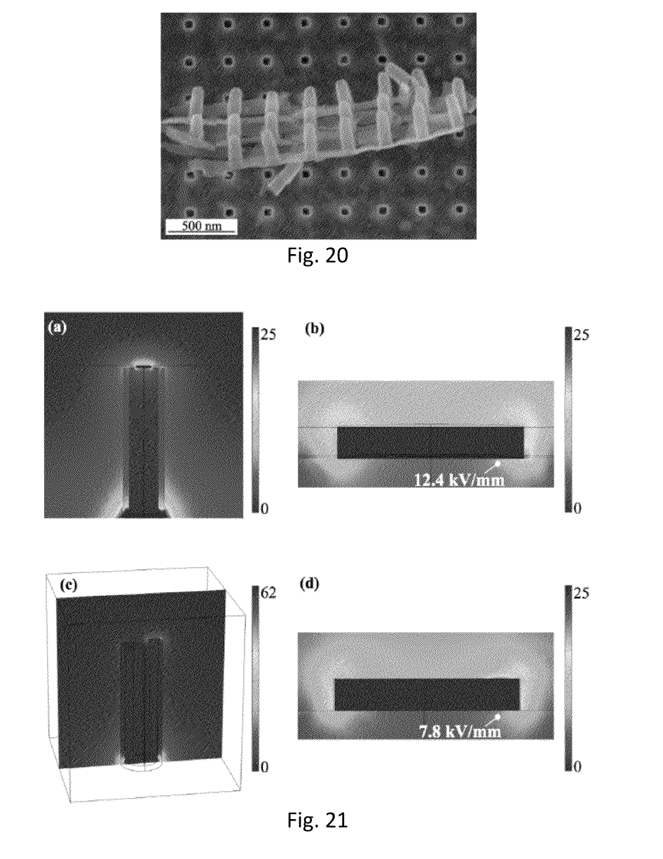

To create “free-standing” PZT nanotubes, a precursor sol-gel solution was vacuum infiltrated into an electron-beam patterned polymeric template (e-resist), coated with 10 nm of Al₂O₃ via atomic layer deposition. After infiltration, the sample was pyrolyzed and annealed in order to crystallize the ferroelectric material and simultaneously decompose the resist. The resulting structure is an array of “free-standing” PZT nanotubes with a thin layer of Al₂O₃ connecting adjacent tubes (FIG. 20). To create “laterally con-strained” PZT nanotubes, the template was created in flow-able oxide resist rather than a thermally decomposable resist: the flowable oxide does not decompose during the thermal treatment for PZT crystallization, leading to lateral constraint of the nanotubes to the passive template.

Hard-templates were fabricated by spin coating Flowable Oxide Resist 16® (FOX 16) on a platinized Si substrate, followed by patterning using electron beam lithography. To fabricate tubes with heights similar to tubes processed in the soft-template, the resist was deposited by spin coating at 5000 rpm for 1 minute followed by a hotplate bake at 80° C. for 4 minutes to remove excess solvent, which resulted in a final template thickness of ˜500 nm. FOX 16 was e-beam exposed directly after spin coating, as previous studies have shown the resist's sensitivity to the time elapsed between coating and exposure. An exposure dose of 2000 μC/cm2 was used to fabricate 100 nm diameter holes with 400 nm pitch. After exposure, the resist was developed in 25% tetra-methyl-ammonium hydroxide (TMAH) at 80° C. and rinsed with gently flowing deionized water for 30 seconds.

Subsequently, the hard template underwent the exact same infiltration processing conditions (including an alumina coating by atomic layer deposition) and heat treatments to create PbZr_{0.52}Ti_{0.48}O₃ (PZT) nanotubes as in the soft-template processing. Creation of small amounts of secondary phases are also possible in the hard templates, however, the same amount of secondary phases should form in both the soft-template and hard-template manufacturing approaches, allowing a comparison of the piezoresponse between the two systems. It is important to note that no secondary phase was observed in the micro-Raman spectra for the PZT nanotubes.

The major difference in configuration for the soft- and hard-template-grown nanotubes is the replacement of the air-gap (relative permittivity, ∈r,ₐᵢᵣ=1) between adjacent tubes with FOX 16 (∈r,_{FOX}=3). This change in surrounding material is expected to affect the electric field distribution within the nanotubes under application of an external voltage, as well as the electromechanical properties of the PZT nanotubes as FOX 16 has a finite mechanical stiffness. From the finite element modeling results (performed using COMSOL Multiphysics® (v.4.2)) for the same applied voltage (1 V), the resulting electric field underneath the AFM tip is significantly larger for the PZT nanotube embedded in the hard-template (12.4 kV/mm) (FIG. 21 a,b) than for the PZT nanotubes created in the soft-template (7.8 kV/mm) (FIG. 21 c,d). Therefore, the material surrounding the PZT nanotube has a crucial impact on the electric field strength in the nanotube itself.

Results and Discussion.

To study the effect of substrate clamping on the freestanding PZT nanotubes, the aspect ratio of the tubes was altered by varying the spin coating conditions of the polymeric template (which ultimately determines the height of the PZT nanotubes). Unless otherwise specified, the nanotube's outer diameter was fixed at 100 nm and the tubes' wall thickness was ˜20 nm. A smaller nanotube wall thickness can lead to absence of ferroelastic domain walls and critical size effects.

To characterize the piezoelectric response of the nanotubes with various boundary conditions, switching-spectroscopy piezoelectric force microscopy (SS-PFM) and nonlinear piezoresponse were collected in a band-excitation setup. For nonlinear piezoelectric measurements, the maximum AC voltage amplitude applied was 9.5 V, which is less than half the coercive voltage. Any measurements at higher voltages would see a convolution of extrinsic contributions from domain wall mobility and increased domain wall density (new domain nucleation). The nonlinear response was analyzed using the Rayleigh law. The ratio of the irreversible to reversible Rayleigh parameters was used as a quantitative measure of the extrinsic contributions to the piezoelectric properties under the assumption that the reversible extrinsic contributions are limited with respect to intrinsic contributions. Although in piezoresponse measurements the Rayleigh parameters are convoluted with the photodiode's and cantilever's sensitivities, the Rayleigh parameters ratio is remarkably independent of tool sensitivities, thereby allowing local nonlinearities to be measured quantitatively.

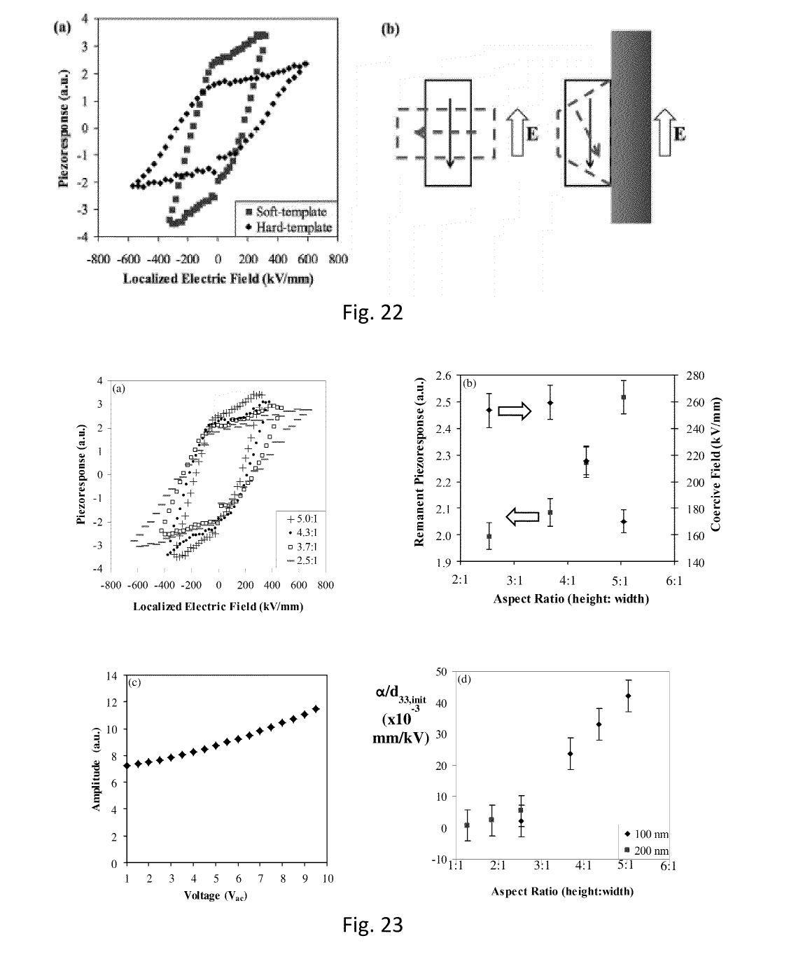

The high-field piezoresponse of nanotubes processed in hard- and soft-templates are compared in FIG. 22a. The data are averaged over the whole area comprising a single nano-tube. All PZT nanotubes have analogous dimensions with a 5:1 (height to width) aspect ratio. The piezoresponse is plotted as a function of normalized local electric field, rather than applied voltage, based on finite element modeling analysis of the field distribution upon application of external voltage through the AFM tip. Although, the field concentration in the laterally clamped nanostructure is much stronger than in the free-standing ones, PZT nanotubes in hard-template show a significant reduction in the remnant piezoresponse compared to the free-standing nanotubes created via the soft-template (Table I).

TABLE I
Piezoresponse and Rayleigh parameters for hard- and soft-templates
grown 5:1 PZT nanotubes with 20 nm-thick PZT walls.

| | Remanent | Coercive | | | |
|---|---|---|---|---|---|
| | Piezoresponse | Field | βd_{33,init} | βα | αd_{33,init} |
| Template | (a.u.) | (kV/mm) | (a.u.) | (a.u.) | (×10⁻³ mm/kV) |
| Hard | 1.6 | 264 | 7.9 | 41.5 | 5.3 |
| Soft | 2.5 | 144 | 2.3 | 95.5 | 41.5 |

When an electric field is applied to the top of the PZT nanotube via the AFM tip, the material deforms longitudinally due to the d₃₃ piezoelectric response. However, any longitudinal response is also accompanied by lateral deformation: i.e., any longitudinal extension should be accompanied by radial contraction. In the case of the hard template-grown nanotubes, the adjacent ˜300 nm-thick FOX 16 (non-piezoelectrically active surrounding media) prevents the nm PZT wall from radial elastic deformation, thus leading also to a reduced longitudinal piezoelectric response, and hence reduced remnant and saturation piezoresponse.

The increase in the coercive field for the laterally constrained PZT material is possibly attributed to the inability of the material to undergo switching via intermediate non-180° polarization reorientation. It has been reported that in ferroelectric materials, switching of dipoles via an intermediate non-180° rotation is energetically more favorable than direct 180° switching. Due to the lateral clamping to the passive template, rotation of the polarization from a direction parallel to the clamped surface, to a direction with normal component to the clamped surface is hindered (FIG. 22b). This implies that a higher amount of energy is required for overall polarization reversal in laterally constrained nanotubes when compared to free-standing nanotubes: the non-180° rotation will require an increased amount of energy to overcome the clamping threshold, or alternatively, the switching will require direct 180° rotation in the laterally constrained tubes, which would also be less energetically favorable.

A comparison of the Rayleigh parameters and their ratios for the hard- and soft-template grown PZT nanotubes is also shown in Table I. The Rayleigh parameters' ratio is larger by almost one order of magnitude in the free-standing nanotubes with respect to the nanotubes laterally constrained by the hard template. Although the individual parameters measured for the Rayleigh parameters include the tool's sensitivity factor (β), their comparison can still offer some input with respect to the observed increase in the Rayleigh parameters” ratio in the free-standing nanotubes. Specifically, the laterally constrained nanotubes show a substantially larger reversible Rayleigh parameter and a much smaller irreversible Rayleigh parameter compared to the free-standing nano-structures. An increased reversible Rayleigh parameter for the tubes embedded in the hard template is potentially due to an increased extrinsic contribution from reversible domain wall vibration and motion. For strong pinning, deep energy wells prevent irreversible motion of internal interfaces, leading to “vibration” (i.e., reversible motion) of domain walls within the potential wells. In comparison, for a weak pinning scenario under the same external fields, the shallow wells allow an enhanced irreversible motion. Therefore, the increase in the reversible contribution for the PZT tubes embedded in the hard template is possibly a result of extensive pinning at the interface with the passive template, which can result in enhanced reversible extrinsic contribution at the expense of irreversible contributions. This experimental result is consistent with theoretical models developed by Ahluwalia et al., which predicted a reduction in saturation and remnant polarization for the finite-sized, constrained ferroelectric systems with respect to the bulk. Finally, it has to be noted that due to the free surface, the electric field vectors may change orientation, close to edges and corners. However, while the presence of in-plane components of electric field can result in polarization rotation and in-plane switching, the classical form of the hysteresis loops does not provide any experimental evidence of either event.

In order to characterize the effect of substrate-clamping, free-standing PZT nanotubes with 100 nm outer diameter and heights ranging from 250 nm to 500 nm, resulting in aspect ratios ranging from 2.5:1 to 5:1, were fabricated. The corresponding piezoresponse hysteresis, measured by SSPFM, is shown in FIG. 23a. PZT nanotubes with lower heights did not show clear switching in the piezoresponse. The electric field generated in the PZT nanotubes under application of the external voltage through the AFM tip was estimated based on results from finite element modeling.

The reduction in the remnant piezoresponse at decreasing PZT nanotubes' aspect ratio (FIG. 23b) is a possible effect of a larger percentage of the overall volume of material clamped to the substrate. Clamping of ferroelastic domains by the substrate has been previously observed for ferroelectric thin films with large residual stress. Residual biaxial tensile stress is often present in ferroelectric thin films processed on platinized silicon substrates, due to differences in the coefficient of thermal expansion of the ferroelectric with respect to the underlying substrate, as well as ferroelectric distortion at the Curie temperature. Due to the tensile nature of the residual stresses in the PZT in proximity of the platinized substrate, it is expected that a large volume of the PZT in such locations would adopt a polarization direction with a large in-plane component. It is plausible that even with the application of high electric fields, such as those supplied during SS-PFM measurements, the domains with a large spontaneous polarization component parallel to the substrate will remain pinned to the substrate, without switching to a polarization direction with larger out of plane component. This lack of re-alignment of domains in the volume of material in close proximity of the substrate will result in domains effectively clamped to the substrate. The suppression of ferroelectric switching would lead to an overall lowered polarization, as well as a reduced piezoresponse. As the aspect ratio increases, however, the polarization is expected to be able to switch again under appropriately large electric fields, due to a relaxation of the interfacial strain through the height of the nanotube: a larger volume of material is, at least partially, unclamped and thus can deform and undergo ferroelastic domain switching via an appropriately high electric field. In thin films, previous studies have shown the existence of a stress field that reduces in amplitude with distance from the underlying substrate. This stress field ultimately alters the effective pinning strength in the material.

The same substrate clamping mechanism could also be responsible for the increase in the coercive field with decreasing nanostructures' aspect ratio. As shown in FIG. 23b, the coercive field is relatively large and invariable for PZT nanotubes with aspect ratios below 4:1. For aspect ratios ˜4:1, the coercive field decreases substantially. The decrease in the coercive field with increasing aspect ratio is consistent with a reduction in the overall volume fraction of material with polarization clamped to the substrate. Thus, to switch the overall polarization direction in low aspect ratio structures, an increased amount of energy is required, leading to an increase in the coercive field as the aspect ratio decreases.

To further investigate the origin of the increase in the remnant piezoresponse and the decrease in coercive field, nonlinear measurements were performed (FIG. 23c) and analyzed using the Rayleigh law. FIG. 23d shows the piezoelectric Rayleigh parameters' ratio, x/d_{33,init}, as a function of PZT nano-tubes' aspect ratio. For nanotubes with aspect ratios<3:1, the x/d_{33,init} ratio was close to null, which indicates negligible extrinsic contributions to the piezoresponse in these samples. This observation is consistent with the inability to switch the piezoresponse (and therefore the polarization) in low aspect ratio PZT nanotubes (<2.5:1) via SS-PFM measurements. As the aspect ratio of the tube increased from 3:1 to 5:1, the Rayleigh parameters' ratio increased, thus identifying a significant enhancement of extrinsic contributions, possibly through ferroelastic, non-180° domain wall motion due to a reduction in the volume fraction, or equivalently the average pinning strength, of material clamped to the substrate.

To verify that the extrinsic contribution is strongly dependent on the aspect ratio of the nanotube and not simply the height of the tube, nanotubes with the same heights but with 200 nm-outer dimension were fabricated, yielding aspect ratios ranging from 1.25:1 to 2.5:1. The outer diameter of the nanotubes was altered by changing the lateral dimensions in the e-resist, patterned via e-beam lithography. For decreasing aspect ratios, the 200 nm diameter tubes also showed a reduction in the response, similar to the trend observed in the 100 nm diameter tubes. This indicates that the height of the nanotube is not the sole factor determining the piezoelectric response but rather it is the ratio of height to lateral size (i.e., the aspect ratio) that influences the clamping. This is consistent with results from theoretical calculations that showed a reduction of in-plane strain in epitaxially patterned PbTiO3 films with increasing aspect ratio (rather than with simple variations in the lateral dimension or film thickness).

In summary, clear trends were observed in the extrinsic contributions to the piezoelectric response as a function of lateral constraint and aspect ratio. A severe reduction in the extrinsic contributions to the piezoelectric response was observed for PZT nanotubes laterally constrained to a hard template with respect to free-standing PZT nanotubes and was attributed to the local clamping of the domains to the passive material along the length of the nanotubes. In addition, as the aspect ratio of the PZT nanotubes decreased, the extrinsic contributions decreased, conceivably through an increase in the overall fraction of material clamped to the underlying substrate. It is interesting to note that the Rayleigh parameters for the PZT nanotubes did not show any saturation within the studied aspect ratio range. It is expected that the irreversible piezoelectric Rayleigh coefficient, will eventually saturate when a threshold aspect ratio is reached, beyond which the substrate-clamping effects have negligible influence on the material's response. Further studies are required to determine the threshold aspect ratio beyond which PZT nanostructures on platinized Si substrates will behave as completely free-standing.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

What is claimed is:

1. A method for fabrication of nanostructured materials comprising the steps of:
(a) Patterning a soft template
(b) Coating the patterned soft template with a conformal layer
(c) Infiltrating the coated soft template with a chemical precursor solution
(d) Heat-treating the infiltrated template to form the nanostructured material.

2. The method of claim 1 wherein the soft template precursor comprises a polymer film having a thickness of about 10 nm to 1 micron.

3. The method of claim 2, wherein the patterning comprises a creating a user-defined pattern in the soft template precursor.

4. The method of claim 1 wherein the conformal layer comprises a metal oxide, a metal or a ceramic material.

5. The method of claim 1 wherein conformal layer is selected from the group consisting of Al₂O₃, titania, ZnO, zirconia, and Pt.

6. The method of claim 1 wherein the conformal layer having a thickness of about 5 nm to about 30 nm.

7. The method of claim 1 wherein the infiltrating comprises immersing the coated soft template in the chemical precursor solution.

8. The method of claim 1 wherein the infiltrating comprises ultrasonic- or vacuum-assisted infiltration.

9. The method of claim 1 wherein the infiltrating comprises ultrasonic- and vacuum-assisted infiltration.

10. The method of claim 1 wherein the chemical precursor solution comprises a precursor selected from the group consisting of PbZr₁₋ₓTiₓO₃, PbTiO₃, BiFeO₃, SiO₂, HfO₂, titania, zirconia, KNbO₃, Bi₄Ti₃O₁₂, SrTi₄Bi₄O₁₅, Na_{0.5}Bi_{0.5}TiO₃, NiFe₂O₄, CoFe₂O₄, and (1-x)[Pb(Mg_{1/3}Nb_{2/3})O₃]-x[PbTiO₃], or mixtures thereof, where x is between 0 and 1.

11. The method of claim 10, wherein the chemical precursor solution comprises a doped or solid solution precursor.

12. The method of claim 1 wherein the chemical precursor solution is doped PbZr₁₋ₓTiₓO₃

13. The method of claim 1 wherein the heat-treating step further comprises a first heat treatment and a second heat treatment.

14. The method of claim 13 wherein the first heat treatment comprises a pyrolysis to partially or completely remove a solvent from the chemical precursor solution.

15. The method of claim 13 wherein the second heat treatment comprises a thermal annealing to remove the soft template and crystallize the precursor.

16. The method of claim 1 further comprising repeating steps (c)-(d)

17. A method fabricating a nanostructured material comprising infiltrating a soft template with a chemical precursor solution and subsequently heat treating the infiltrated template to produce the nanostructured material.

18. The method of claim 17, wherein the soft template has previously been patterned with a user-defined pattern.

19. The method of claim 17, wherein the infiltrating comprises ultrasonic- and vacuum-assisted infiltration.

20. A material comprising a ferroic nanostructure, wherein the nanostructure has an aspect ratio of about 1:1 to about 20:1.

21. The material of claim 20 wherein the nanostructure has an aspect ratio of about 1:1 to about 10:1.

22. The material of claim 20 wherein the nanostructure has an aspect ratio of about 2:1 to about 5:1.

23. The material of claim 20 wherein the nanostructure has an outer diameter of about 30 nm to about 500 nm.

24. The material of claim 20 wherein the nanostructure has a height of about 50 nm to about 1 micron.

25. The material of claim 20 wherein the nanostructure has a wall thickness of at least about 5 nm, at least about 10 nm, at least about 50 nm

26. The material of claim 20, wherein the ferroic nanostructure comprises a user-defined pattern of ferroic nanostructures.
